(19) United States
(12) Patent Application Publication
(10) Pub. No.: US 2025/0393428 A1
(43) Pub. Date: Dec. 25, 2025

(54) DISPLAY PANEL AND METHOD FOR MANUFACTURING AND DRIVING SAME, AND DISPLAY DEVICE

(71) Applicant: BOE Technology Group Co., Ltd., Beijing (CN)

(72) Inventors: Mingche HSIEH, Beijing (CN); Hao ZHANG, Beijing (CN); Xinbin HAN, Beijing (CN)

(21) Appl. No.: 18/881,265

(22) PCT Filed: May 15, 2024
(86) PCT No.: PCT/CN2024/093285

§ 371 Date: Jan. 4, 2025

(30) Foreign Application Priority Data
Jun. 30, 2023 (CN) 202310802028.6

(51) Int. Cl. H10K 59/35; G09G 3/3233; H10K 59/12; H10K 59/121; H10K 59/122; H10K 59/126; H10K 59/38

(52) U.S. Cl. CPC H10K 59/353; G09G 3/3233; H10K 59/1201; H10K 59/1213; H10K 59/1216; H10K 59/122; H10K 59/126; H10K 59/352; H10K 59/38; G09G 2320/068

(57) ABSTRACT

Provided is a display panel. The display panel includes a base substrate, wherein the base substrate includes a plurality of pixel sub-regions, wherein each of the plurality of pixel sub-regions includes a plurality of pixel unit regions; a plurality of first sub-pixels and a plurality of second sub-pixels that are in one-to-one correspondence and have different colors in the plurality of pixel unit regions in the plurality of pixel sub-regions; and a pixel definition layer, an encapsulation layer, and a plurality of light-shielding layers that are stacked on a side of the light-emitting unit layer in the direction away from the base substrate in sequence, wherein the pixel definition layer includes a plurality of openings and a plurality of pixel definition portions surrounding the plurality of openings.

This application is a U.S. national stage of international application No. PCT/CN2024/093285, filed on May 15, 2024, which claims priority to Chinese Patent Application No. 202310802028.6, filed on Jun. 30, 2023 and entitled “DISPLAY PANEL, PREPARATION METHOD THEREOF, DRIVING METHOD AND DISPLAY DEVICE,” the disclosure of which is herein incorporated by reference in its entirety.

### TECHNICAL FIELD

The present disclosure relates to the technical field of display, and in particular, relates to a display panel and a method for manufacturing and driving the same, and a display device.

### BACKGROUND

With the development of the display technologies, display products, for example, mobile phones, computers, and the like are widely used. During use of the products, users generally have an intention to share display information with others on one hand, while also desiring privacy in some specific scenarios to prevent the display information from being peeped at.

### SUMMARY

A display panel and a method for manufacturing and driving the same, and a display device are provided. The technical solutions are as follows.

In some embodiments of the present disclosure, a display panel is provided. The display panel includes:
a base substrate, including: a plurality of pixel sub-regions, wherein each of the plurality of pixel sub-regions includes a plurality of pixel unit regions, each of the plurality of pixel unit regions including a first pixel unit region and a second pixel unit region;
a plurality of first sub-pixels and a plurality of second sub-pixels that are in one-to-one correspondence and have different colors in the plurality of pixel unit regions in the plurality of pixel sub-regions, wherein the plurality of first sub-pixels are disposed in the first pixel unit region, the plurality of second sub-pixels are disposed in the second pixel unit region, and each of the plurality of first sub-pixels and the plurality of second sub-pixels includes a pixel circuit layer and a light-emitting unit layer that are stacked in a direction away from the base substrate in sequence; and
a pixel definition layer, an encapsulation layer, and a plurality of light-shielding layers that are stacked on a side of the light-emitting unit layer in the direction away from the base substrate in sequence, wherein the pixel definition layer includes a plurality of openings and a plurality of pixel definition portions surrounding the plurality of openings, light-emitting unit layers of any adjacent two sub-pixels in the plurality of first sub-pixels and the plurality of second sub-pixels are disposed in one of the plurality of openings and defined by the pixel definition layer, the plurality of light-shielding layers include a plurality of light shield portions that are spaced apart, and an orthographic projection of each of the plurality of light shield portions on the base substrate is overlapped with an orthographic projection of one of the plurality of pixel definition portions defining the plurality of first sub-pixels on the base substrate;
wherein the pixel circuit layer is configured to form a pixel circuit, and the light-emitting unit layer is configured to form a light-emitting element, wherein the pixel circuit includes a drive circuit and a switch circuit, and pixel circuits in the plurality of first sub-pixels and the plurality of second sub-pixels that are in one-to-one correspondence include different switch circuits and share a same drive circuit;
wherein the switch circuit is coupled to a switch control terminal, the drive circuit, and the light-emitting element, and is configured to control, based on a switch control signal supplied by the switch control terminal, the drive circuit and the light-emitting element to be on and off, and the drive circuit is configured to generate a drive signal for driving the light-emitting element to emit light.

In some embodiments, in the plurality of first sub-pixels and the plurality of second sub-pixels that are in one-to-one correspondence, an area of the light-emitting element in each of the plurality of first sub-pixels is less than an area of the light-emitting element in each of the plurality of second sub-pixels.

In some embodiments, the first pixel unit region includes a plurality of pixel unit sub-regions defined by the plurality of pixel definition portions, and
the light-emitting unit layer includes an anode, a light-emitting layer, and a cathode that are stacked in the direction away from the base substrate in sequence, wherein the anode of each of the plurality of first sub-pixels in the first pixel unit region includes a plurality of anode portions coupled to each other in the plurality of pixel unit sub-regions.

In some embodiments, shapes of the plurality of pixel unit sub-region in the first pixel unit region are different from a shape of the second pixel unit region.

In some embodiments, the display panel further includes:
a spacer layer between each two adjacent layers of the plurality of light-shielding layers;
a first overcoat layer on a side, away from the base substrate, of the plurality of light-shielding layers;
a touch layer and a second overcoat layer between the encapsulation layer and the plurality of light-shielding layers and stacked in the direction away from the base substrate in sequence; wherein
the touch layer includes a plurality of touch electrodes that are spaced apart, wherein each of the plurality of touch electrodes includes an interlayer dielectric layer, a first electrode layer, and a second electrode layer that are stacked in the direction away from the base substrate in sequence, and
an orthographic projection of each of the plurality of touch electrodes on the base substrate is overlapped with an orthographic projection of a portion, between two adjacent of the plurality of pixel unit regions, of the pixel definition layer on the base substrate.

In some embodiments, the display panel includes two light-shielding layers, wherein a distance between the two light-shielding layers is greater than 5 microns, and
each of the two light-shielding layers includes a black matrix layer or a black pixel definition layer.

In some embodiments, the display panel further includes: a color filter portion between each two adjacent of the plurality of light shield portions in at least one layer of the plurality of light-shielding layers.

In some embodiments, in the plurality of first sub-pixels and the plurality of second sub-pixels that are in one-to-one correspondence, the drive circuit of each of the sub-pixels is coupled to a gate signal terminal, a data signal terminal, and a drive power terminal and is configured to generate the drive signal based on a gate drive signal supplied by the gate signal terminal, a data signal supplied by the data signal terminal, and a drive power signal supplied by the drive power terminal, and the switch circuit of each of the sub-pixels includes a first switch transistor, wherein
a gate electrode of the first switch transistor is coupled to the switch control terminal, a first electrode of the first switch transistor is coupled to the drive circuit, and a second electrode of the first switch transistor is coupled to the light-emitting element.

In some embodiments, the drive circuit of each of the sub-pixels further includes a first data write transistor, a first drive transistor, and a first storage capacitor,

Wherein a gate electrode of the first data write transistor is coupled to the gate signal terminal, a first electrode of the first data write transistor is coupled to the data signal terminal, and a second electrode of the first data write transistor is coupled to a first terminal of the first storage capacitor; a second terminal of the first storage capacitor is coupled to the drive power terminal; and a gate electrode of the first drive transistor is coupled to the first terminal of the first storage capacitor, a first electrode of the first drive transistor is coupled to the drive power terminal, and a second electrode of the first drive transistor is coupled to the first electrode of the first switch transistor.

In some embodiments, in the plurality of first sub-pixels and the plurality of second sub-pixels that are in one-to-one correspondence, the switch circuit of at least one sub-pixel is coupled to the drive power terminal and the drive circuit, is configured to control, based on the switch control signal, the drive power terminal and the drive circuit to be on and off, and further includes a second switch transistor,
wherein a gate electrode of the second switch transistor is coupled to the switch control terminal, a first electrode of the second switch transistor is coupled to the drive power terminal, and a second electrode of the second switch transistor is coupled to the drive circuit.

In some embodiments, the drive circuit of each of the sub-pixels includes a second data write transistor, a second drive transistor, a compensation transistor, and a second storage capacitor,
wherein a gate electrode of the second data write transistor and a gate electrode of the compensation transistor are coupled to the gate signal terminal, a first electrode of the second data write transistor is coupled to the data signal terminal, and a second electrode of the second data write transistor is coupled to a first electrode of the second drive transistor; a first electrode of the compensation transistor is coupled to a second electrode of the second drive transistor, and a second electrode of the compensation transistor is coupled to a gate electrode of the second drive transistor; a first electrode of the second drive transistor is coupled to the second electrode of the second switch transistor; and a first terminal of the second storage capacitor is coupled to the gate electrode of the second drive transistor, and a second terminal of the second storage capacitor is coupled to the drive power terminal.

In some embodiments, in different switch circuits in the pixel circuits in the plurality of first sub-pixels and the plurality of second sub-pixels that are in one-to-one correspondence, types of switch transistors are the same, and the different switch circuits are coupled to different switch control terminals; or
in different switch circuits in the pixel circuits in the plurality of first sub-pixels and the plurality of second sub-pixels that are in one-to-one correspondence, types of switch transistors are different, and the different switch circuits share a same switch control terminal.

In some embodiments, the display panel includes a plurality of first pixels in the plurality of pixel sub-regions, wherein each of the plurality of first pixels includes a plurality of sub-pixels in different colors, each of the plurality of sub-pixels including one of the plurality of first sub-pixels and one of the plurality of second sub-pixels that are in one-to-one correspondence; or
the display panel includes a plurality of first pixels and a plurality of second pixels in the plurality of pixel sub-regions, wherein each of the plurality of first pixels includes the plurality of first sub-pixels in different colors, and each of the plurality of second pixels includes the plurality of second sub-pixels that are in one-to-one correspondence to the plurality of first sub-pixels in different colors.

In some embodiments of the present disclosure, a method for manufacturing a display panel is provided. The method is applicable to manufacturing the display panel according to the above embodiments. The method includes:
providing a base substrate, the base substrate including a plurality of pixel sub-regions, wherein each of the plurality of pixel sub-regions includes a plurality of pixel unit regions, each of the plurality of pixel unit regions including a first pixel unit region and a second pixel unit region;
forming a plurality of first sub-pixels and a plurality of second sub-pixels that are in one-to-one correspondence and have different colors in the plurality of pixel unit regions in the plurality of pixel sub-regions, wherein the plurality of first sub-pixels are disposed in the first pixel unit region, the plurality of second sub-pixels are disposed in the second pixel unit region, and each of the plurality of first sub-pixels and the plurality of second sub-pixels includes a pixel circuit layer and a light-emitting unit layer that are stacked in a direction away from the base substrate in sequence, wherein the pixel circuit layer is configured to form a pixel circuit, and the light-emitting unit layer is configured to form a light-emitting element; and
forming a pixel definition layer, an encapsulation layer, and a plurality of light-shielding layers that are stacked on a side of the light-emitting unit layer in the direction away from the base substrate in sequence, wherein the formed pixel definition layer includes a plurality of openings and a plurality of pixel definition portions surrounding the plurality of openings, light-emitting unit layers of any adjacent two sub-pixels in the plurality of first sub-pixels and the plurality of second sub-pixels are disposed in one of the plurality of openings and defined by one of the plurality of pixel definition portions, the plurality of formed light-shielding layers include a plurality of light shield portions that are spaced apart, and an orthographic projection of each of the plurality of light shield portions on the base substrate ais overlapped with an orthographic projection of one of the plurality of pixel definition portions defining the plurality of first sub-pixels on the base substrate;
wherein the formed pixel circuit includes a drive circuit and a switch circuit, and pixel circuits in the plurality of first sub-pixels and the plurality of second sub-pixels that are in one-to-one correspondence include different switch circuits and share a same drive circuit;
wherein the switch circuit is coupled to a switch control terminal, the drive circuit, and the light-emitting element, and is configured to control, based on a switch control signal supplied by the switch control terminal, the drive circuit and the light-emitting element to be on and off, and the drive circuit is configured to generate a drive signal for driving the light-emitting element to emit light.

In some embodiments of the present disclosure, a method for driving a display panel is provided. The method is applicable to the display panel according to the above embodiments. The method includes:
supplying, in response to a peep-proof instruction, a switch control signal at a valid potential to a switch control terminal coupled to a pixel circuit in a first sub-pixel, wherein a switch circuit in the pixel circuit in the first sub-pixel controls, based on the switch control signal at the valid potential, a drive circuit and a light-emitting element therein to be on;
supplying, in response to the peep-proof instruction, a switch control signal at an invalid potential to a switch control terminal coupled to a pixel circuit in a second sub-pixel corresponding to the first sub-pixel, wherein a switch circuit in the pixel circuit in the second sub-pixel controls, based on the switch control signal at the invalid potential, a drive circuit and a light-emitting element therein to be decoupled; or, supplying, in response to the peep-proof instruction, a pulse switch control signal to a switch control terminal coupled to a pixel circuit in a second sub-pixel, wherein a switch circuit in the pixel circuit in the second sub-pixel controls, based on the pulse switch control signal, a drive circuit and a light-emitting element therein to be on and off periodically;
supplying, in response to a share instruction, the switch control signal at the valid potential to the switch control terminal coupled to the pixel circuit in the second sub-pixel, wherein the switch circuit in the pixel circuit in the second sub-pixel controls, based on the switch control signal at the valid potential, the drive circuit and the light-emitting element therein to be on; and
supplying, in response to the share instruction, the switch control signal at the valid potential to the switch control terminal coupled to the pixel circuit in the first sub-pixel, wherein the switch circuit in the pixel circuit in the first sub-pixel controls, based on the switch control signal at the valid potential, the drive circuit and the light-emitting element therein to be on; or, supplying, in response to the share instruction, a pulse switch control signal to the switch control terminal coupled to the pixel circuit in the first sub-pixel, wherein the switch circuit in the pixel circuit in the first sub-pixel controls, based on the pulse switch control signal, the drive circuit and the light-emitting element therein to be on and off periodically;
wherein in the case that the drive circuit and the light-emitting element are conducted, a drive signal generated by the drive circuit is transmitted to the light-emitting element to drive the light-emitting element to emit light.

In some embodiments of the present disclosure, a display device is provided. The display device includes: a power supply assembly, and the display panel according to the above embodiments;
wherein the power supply assembly is coupled to the display panel and is configured to supply power to the display panel.

### BRIEF DESCRIPTION OF DRAWINGS

For clearer description of the technical solutions according to the embodiments of the present disclosure, the following briefly introduces the accompanying drawings required for describing the embodiments. Apparently, the accompanying drawings in the following description show merely some embodiments of the present disclosure, and persons of ordinary skill in the art may still derive other drawings from these accompanying drawings without creative efforts.

FIG. 1 is a schematic structural diagram of a display panel according to some embodiments of the present disclosure;

FIG. 2 is a schematic diagram of film layers of a display panel according to some embodiments of the present disclosure;

FIG. 3 is a schematic diagram of emission of light by a sub-pixel in a display panel according to some embodiments of the present disclosure;

FIG. 4 is a schematic diagram of emission of light by a sub-pixel in a display panel according to some embodiments of the present disclosure;

FIG. 5 is a structural block diagram of a sub-pixel according to some embodiments of the present disclosure;

FIG. 6 is a schematic diagram of organization of sub-pixels in a display panel according to some embodiments of the present disclosure;

FIG. 7 is a schematic diagram of organization of sub-pixels in a display panel according to some embodiments of the present disclosure;

FIG. 8 is a schematic diagram of organization of sub-pixels in a display panel according to some embodiments of the present disclosure;

FIG. 9 is a schematic diagram of organization of sub-pixels in a display panel according to some embodiments of the present disclosure;

FIG. 10 is a schematic diagram of division of regions in a display panel according to some embodiments of the present disclosure;

FIG. 11 is a schematic diagram of part of film layers of a display panel according to some embodiments of the present disclosure;

FIG. 12 is a schematic diagram of division of regions in a display panel according to some embodiments of the present disclosure;

FIG. 13 is a schematic diagram of division of regions in a display panel according to some embodiments of the present disclosure;

FIG. 14 is a schematic diagram of division of regions in a display panel according to some embodiments of the present disclosure;

FIG. 15 is a schematic diagram of film layers of a display panel according to some embodiments of the present disclosure;

FIG. 16 is a schematic diagram of film layers of a display panel according to some embodiments of the present disclosure;

FIG. 17 is a schematic diagram of film layers of a display panel according to some embodiments of the present disclosure;

FIG. 18 is a structural block diagram of a sub-pixel according to some embodiments of the present disclosure;

FIG. 19 is a schematic structural diagram of a pixel circuit in a sub-pixel according to some embodiments of the present disclosure;

FIG. 20 is a schematic structural diagram of a pixel circuit in a sub-pixel according to some embodiments of the present disclosure;

FIG. 21 is a structural block diagram of a sub-pixel according to some embodiments of the present disclosure;

FIG. 22 is a schematic structural diagram of a pixel circuit in a sub-pixel according to some embodiments of the present disclosure;

FIG. 23 is a schematic structural diagram of a pixel circuit in a sub-pixel according to some embodiments of the present disclosure;

FIG. 24 is a schematic structural diagram of a pixel circuit in a sub-pixel according to some embodiments of the present disclosure;

FIG. 25 is a flowchart of a method for manufacturing a display panel according to some embodiments of the present disclosure;

FIG. 26 is a schematic diagram of part of film layers of a display panel on the basis of the structure shown in FIG. 2;

FIG. 27 is a schematic diagram of part of film layers of a display panel on the basis of the structure shown in FIG. 2;

FIG. 28 is a schematic diagram of part of film layers of a display panel on the basis of the structure shown in FIG. 2;

FIG. 29 is a schematic diagram of part of film layers of a display panel on the basis of the structure shown in FIG. 2;

FIG. 30 is a schematic diagram of part of film layers of a display panel on the basis of the structure shown in FIG. 2;

FIG. 31 is a schematic diagram of part of film layers of a display panel on the basis of the structure shown in FIG. 16;

FIG. 32 is a schematic diagram of part of film layers of a display panel on the basis of the structure shown in FIG. 16;

FIG. 33 is a schematic diagram of part of film layers of a display panel on the basis of the structure shown in FIG. 16;

FIG. 34 is a schematic diagram of part of film layers of a display panel on the basis of the structure shown in FIG. 16;

FIG. 35 is a schematic diagram of part of film layers of a display panel on the basis of the structure shown in FIG. 16;

FIG. 36 is a schematic diagram of part of film layers of a display panel on the basis of the structure shown in FIG. 16;

FIG. 37 is a schematic diagram of part of film layers of a display panel on the basis of the structure shown in FIG. 16;

FIG. 38 is a flowchart of a method for driving a display panel according to some embodiments of the present disclosure;

FIG. 39 is a schematic diagram of signal timing on the basis of the structure shown in FIG. 19;

FIG. 40 is a schematic diagram of a viewing angle curve on the basis of timing shown in FIG. 39;

FIG. 41 is a schematic diagram of signal timing on the basis of the structure shown in FIG. 19;

FIG. 42 is a schematic diagram of signal timing on the basis of the structure shown in FIG. 19;

FIG. 43 is a schematic diagram of signal timing on the basis of the structure shown in FIG. 20;

FIG. 44 is a schematic diagram of signal timing on the basis of the structure shown in FIG. 22;

FIG. 45 is a schematic diagram of signal timing on the basis of the structure shown in FIG. 23;

FIG. 46 is a schematic diagram of signal timing on the basis of the structure shown in FIG. 24; and

FIG. 47 is a schematic structural diagram of a display device according to some embodiments of the present disclosure.

### DETAILED DESCRIPTION

For clearer descriptions of the objects, technical solutions, and advantages of the present disclosure, the embodiments of the present disclosure are described in detail hereinafter in combination with the accompanying drawings.

Based on the sharing and peep-proof requirements, some practices provide a display technology capable of switching between a sharing mode and a peep-proof mode. Illustratively, a peep-proof film is attached on a light-emitting face of the display screen, the peep-proof film blocks the display screen to achieve a peep-proof effect where peep-proof is desired, and the peep-proof film is removed where peep-proof is not desired. Alternatively, an additional liquid crystal layer is added in the common liquid crystal display panel, and a light-emitting angle of the display screen is limited by turning of liquid crystal molecules in the liquid crystal layer to achieve the peep-proof or sharing.

However, the method in some practices only switches between the sharing mode and the peep-proof mode and fails to flexibly control the peep-proof angle, and thus has poor peep-proof flexibility.

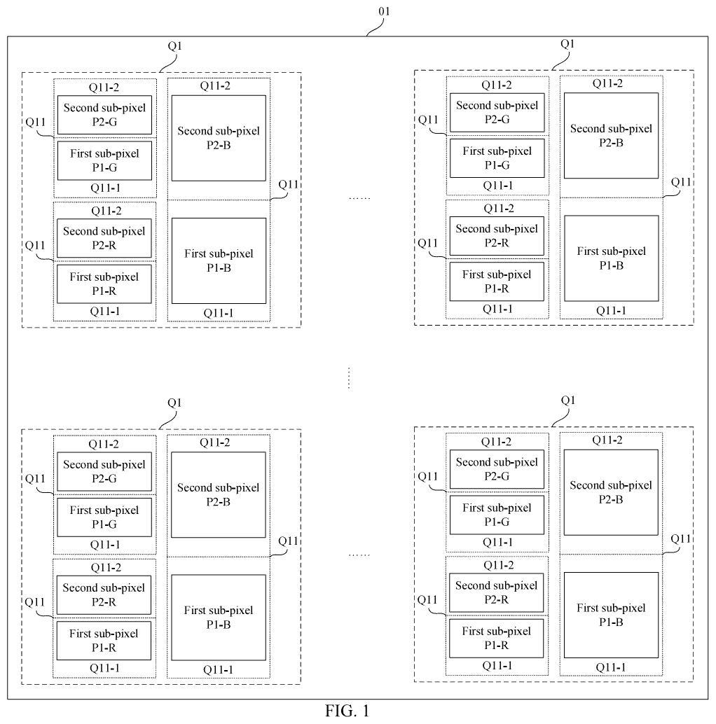

FIG. 1 is a schematic structural diagram of a display panel according to some embodiments of the present disclosure. As shown in FIG. 1, the display panel includes a base substrate 01.

The base substrate 01 includes a plurality of pixel sub-regions Q1. Each of the plurality of pixel sub-regions Q1 includes a plurality of pixel unit regions Q11, and each of the plurality of pixel unit regions Q11 including a first pixel unit region Q11-1 and a second pixel unit region Q11-2. The display panel further includes a plurality of first sub-pixels P1 and a plurality of second sub-pixels P2 that are in one-to-one correspondence and have different colors in the plurality of pixel unit regions Q11 in the plurality of pixel sub-regions Q1. The plurality of first sub-pixels P1 are disposed in the first pixel unit region Q11-1, and the plurality of second sub-pixels P2 are disposed in the second pixel unit region Q11-2.

Illustratively, in the display panel shown in FIG. 1, each pixel sub-region Q1 in the base substrate 01 includes three pixel unit regions Q11 and three first sub-pixels P1 and three second sub-pixels P2 that are in one-to-one correspondence in the three pixel unit regions Q11. That is, each first sub-pixel P1 is disposed in a first pixel unit region Q11-1 in a pixel unit region Q11, and different first sub-pixels P1 are disposed in different first pixel unit regions Q11-1 in different pixel unit regions Q11. Similarly, each second sub-pixel P2 is disposed in a second pixel unit region Q11-2 in a pixel unit region Q11, and different second sub-pixels P2 are disposed in different second pixel unit regions Q11-2 in different pixel unit regions Q11. In addition, in a same pixel unit region Q11, the first sub-pixel P1 in the first pixel unit region Q11-1 and the second sub-pixel P2 in the second pixel unit region Q11-2 are in the same color. For example, referring to FIG. 1, for each pixel sub-region Q1, colors of the three first sub-pixels P1 in the three pixel unit regions Q11 are green (G), red (R), and blue (B), which are marked as P1-G, P1-R, and P1-B. Correspondingly, colors of the three second sub-pixels P2 are green (G), red (R), and blue (B), which are marked as P2-G, P2-R, and P2-B. The green first sub-pixel P1-G and the green second sub-pixel P2-G are disposed in the first pixel unit region Q11-1 and the second pixel unit region Q11-2 in the same pixel unit region Q11. The red first sub-pixel P1-R and the red second sub-pixel P2-R are disposed in the first pixel unit region Q11-1 and the second pixel unit region Q11-2 in the same pixel unit region Q11. The blue first sub-pixel P1-B and the blue second sub-pixel P2-B are disposed in the first pixel unit region Q11-1 and the second pixel unit region Q11-2 in the same pixel unit region Q11. The above description of positions are illustrative.

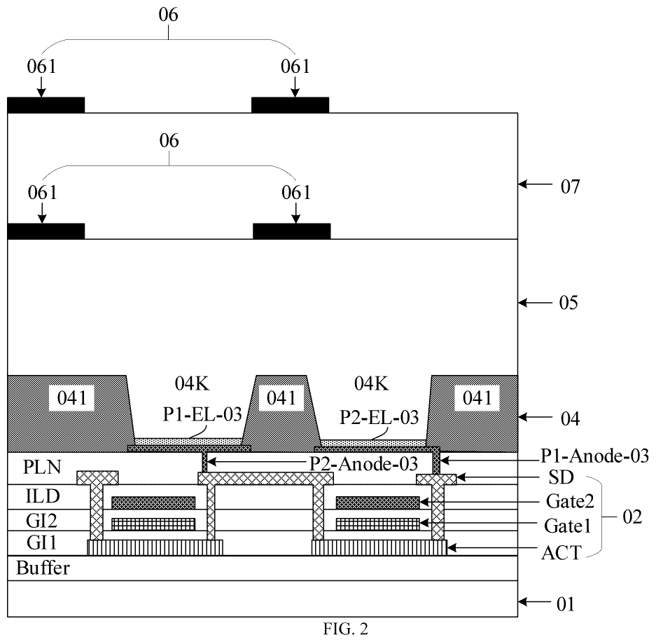

On the basis of FIG. 1, it can be seen referring to FIG. 2 that the first sub-pixel P1 and the second sub-pixel P2 each includes a pixel circuit layer 02 and a light-emitting unit layer 03 that are stacked in a direction away from the base substrate 01 in sequence. The pixel circuit layer 02 is configured to form a pixel circuit 021, and the light-emitting unit layer 03 is configured to form a light-emitting element 031. The pixel circuit 021 is coupled to the light-emitting element 031 and is configured to drive the light-emitting element 031 to emit light.

In addition, the display panel further includes a pixel definition layer PDL 04, also referred to as a PDL layer, an encapsulation layer 05, and a plurality of light-shielding layers 06 that are stacked on a side of the light-emitting unit layer 03 in the direction away from the base substrate 01 in sequence. In some embodiments, the encapsulation layer 05 uses thin film encapsulation (TFE), and correspondingly, the encapsulation layer 05 is also referred to as a TFE layer.

The pixel definition layer 04 includes a plurality of openings 04K and a plurality of pixel definition portions 041 surrounding the plurality of openings 04K, light-emitting unit layers 03 of any adjacent two sub-pixels in the plurality of first sub-pixels P1 and the plurality of second sub-pixels P2 are disposed in one of the plurality of openings 04K and defined by one of the plurality of pixel definition portions 041. The plurality of light-shielding layers 06 include a plurality of light shield portions 061 that are spaced apart, and an orthographic projection of each of the plurality of light shield portions 061 on the base substrate 01 is overlapped with an orthographic projection of one of the plurality of pixel definition portions 041 defining the plurality of first sub-pixels P1 on the base substrate 01 (referred to as a first overlapping region). the orthographic projection of each of the plurality of light shield portions 061 in each light-shielding layer 06 on the base substrate 01 is overlapped with an orthographic projection of one of the plurality of pixel definition portions 041 defining the plurality of first sub-pixels P1 on the base substrate 01, and is not overlapped with an orthographic projection of one of the plurality of pixel definition portions 041 defining the plurality of second sub-pixels P2 on the base substrate 01. In some embodiments, an orthographic projection of each of the plurality of light shield portions 061 in some of the plurality of light-shielding layers 06 on the base substrate 01 is overlapped with the orthographic projection of one of the plurality of pixel definition portions 041 defining the plurality of second sub-pixels P2 on the base substrate 01 (referred to as a second overlapping region). An area of the second overlapping region is less than an area of the first overlapping region.

Illustratively, referring to FIG. 2 to FIG. 4, the shown display panel includes two light-shielding layers 06 stacked in sequence. In the shown two light-shielding layers 06, an orthographic projection of each of the plurality of light shield portions 061 in each light-shielding layer 06 on the base substrate 01 is completely overlapped with the orthographic projection of one of the plurality of pixel definition portions 041 defining the plurality of first sub-pixels P1 on the base substrate 01. In addition, in the two light-shielding layers 06 shown in FIG. 2, an orthographic projection of each of the plurality of light shield portions 061 in the light-shielding layer 06 close to the base substrate 01 on the base substrate 01 is overlapped with the orthographic projection of one of the plurality of pixel definition portions 041 defining the plurality of second sub-pixels P2 on the base substrate 01, an orthographic projection of each of the plurality of light shield portions 061 in the light-shielding layer 06 away from the base substrate 01 on the base substrate 01 is overlapped with the orthographic projection of one of the plurality of pixel definition portions 041 defining the plurality of second sub-pixels P2 on the base substrate 01, and the orthographic projection of each of the plurality of light shield portions 061 on the base substrate 01 is within the orthographic projection of one of the plurality of pixel definition portions 041 on the base substrate 01.

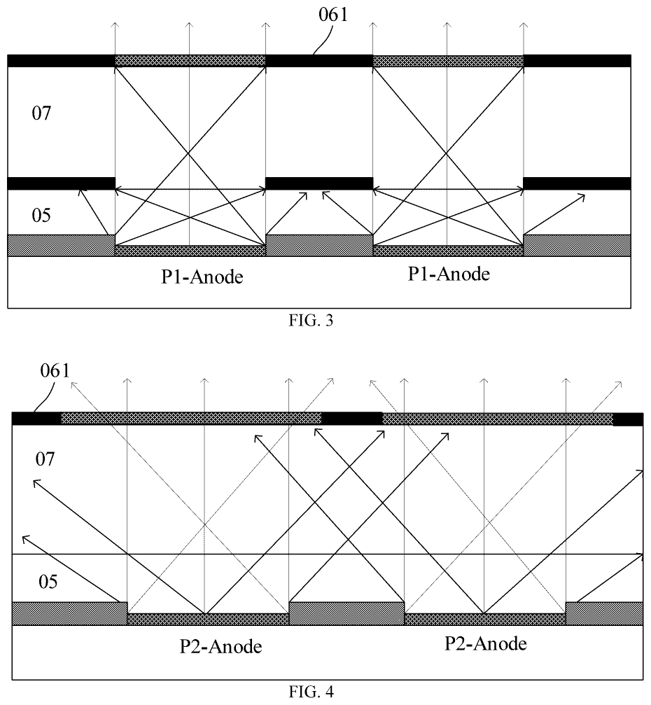

On this basis, it can be seen by comparing the light shown in FIG. 3 and FIG. 4 that a side of the pixel definition portion 041 defining the first sub-pixel P1 is covered by the light shield portion 061, and thus light emitted by the light-emitting unit layer 03 is shielded by the light shield portion 061. That is, the light shield portion 061 limits the light emitting angle to some extent to form a peep-proof angle. In addition, a side of the pixel definition portion 041 defining the second sub-pixel P2 is partially covered by the light shield portion 061 with a less area. Thus, for the first sub-pixel P1, the light emitting angle is greater, and the peep-proof angle is less. On this basis, in the embodiments of the present disclosure, the first sub-pixel P1 may be referred to as a peep-proof sub-pixel, and the first pixel unit region Q11-1 may be referred to as a peep-proof region; and the second sub-pixel P2 may be referred to as a normal sub-pixel, and the second pixel unit region Q11-2 may be referred to as a normal region. The plurality of light-shielding layers 06 are set to limit the light emitting angle and reduce emitted light with a viewing angle. It can be further seen referring to FIG. 2 that the light-emitting unit layer 03 includes an anode Anode, a light-emitting layer EL, and a cathode (not shown) that are stacked in sequence. A portion defined by the pixel definition portion 041 herein may be the anode Anode of the light-emitting unit layer 03.

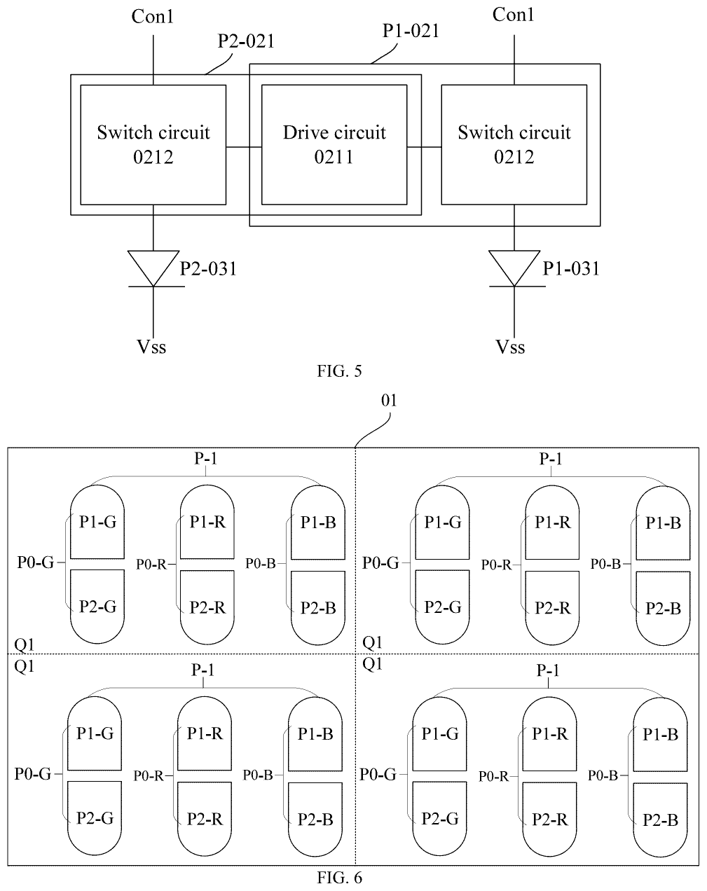

On the basis of FIG. 2, it can be seen referring to FIG. 5 that the pixel circuit 021 in each sub-pixel in the embodiments of the present disclosure includes a drive circuit 0211 and a switch circuit 0212, and pixel circuits 021 in the plurality of first sub-pixels P1 and the plurality of second sub-pixels P2 that are in one-to-one correspondence include different switch circuits 0212 and share a same drive circuit 0211.

The switch circuit 0212 is coupled to a switch control terminal Con1, the drive circuit 0211, and the light-emitting element 031, and is configured to control, based on a switch control signal supplied by the switch control terminal Con1, the drive circuit 0211 and the light-emitting element 031 to be on and off, and the drive circuit 0211 is configured to generate a drive signal (for example, a drive current) for driving the light-emitting element 031 to emit light.

For example, in the case that a potential of the switch control signal supplied by the switch control terminal Con1 is a valid potential (also referred to as a first potential), the switch circuit 0212 controls the drive circuit 0211 and the light-emitting element 031 to be on, such that the drive signal generated by the drive circuit 0211 is transmitted to the light-emitting element 031 to drive the light-emitting element to emit light. In the case that the potential of the switch control signal supplied by the switch control terminal Con1 is an invalid potential (also referred to as a second potential), the switch circuit 0212 controls the drive circuit 0211 and the light-emitting element 031 to be decoupled.

In the case that the switch circuit 0212 in the first sub-pixel P1 controls the drive circuit 0211 and the light-emitting element 031 to be on, the light-emitting element 031 in the first sub-pixel P1 is lightened up, that is, emits light. In the case that the switch circuit 0212 in the second sub-pixel P2 controls the drive circuit 0211 and the light-emitting element 031 to be on, the light-emitting element 031 in the second sub-pixel P2 is lightened up, that is, emits light. In some embodiments, in conjunction with the above description, the light-emitting element 031 in the first sub-pixel P1 and the light-emitting element 031 in the second sub-pixel P2 are controlled to be lightened up simultaneously to achieve the sharing function, and only the light-emitting element 031 in the first sub-pixel P1 is controlled to be lightened up to achieve the peep-proof function. That is, the display panel according to the embodiments of the present disclosure switches f between the sharing mode and the peep-proof mode. In addition, as the first sub-pixel P1 (the peep-proof sub-pixel) and the second sub-pixel P2 (the normal sub-pixel) that are in one-to-one correspondence include different switch circuits 0212, by flexibly setting the switch control signals supplied to the switch control terminals Con1 coupled to different switch circuits 0212, the different switch circuits 0212 flexibly control the light-emitting states (that is, emitting light or not emitting light) and the luminance of the peep-proof sub-pixel and the normal sub-pixel, such that the peep-proof sub-pixel and the normal sub-pixel are lightened up separately, and thus the peep-proof angle is flexibly controlled.

That is, in the embodiments of the present disclosure, as the pixel circuits in the first sub-pixel P1 (the peep-proof sub-pixel) and the second sub-pixel P2 (the normal sub-pixel) that are in one-to-one correspondence share a same drive circuit 0211 and include different switch circuits 0212, the great peep-proof flexibility is ensured on the premise that the pixel structure is simplified to save cost and facilitate high resolution design.

In some embodiments, referring to FIG. 5, the switch circuit 0212 is coupled to the anode of the light-emitting element 031, the cathode of the light-emitting element 031 is further coupled to a pull-down power terminal Vss, and the light-emitting layer in the light-emitting element 031 emits light under a potential difference between the drive signal received by the anode and the pull-down power signal supplied by the pull-down power supply Vss received by the cathode. One of the valid potential and the invalid potential is lower than the other of the valid potential and the invalid potential. For example, for a circuit including a P-type transistor, the received valid potential is lower than the invalid potential. For a circuit including a N-type transistor, the received valid potential is higher than the invalid potential.

In summary, a display panel is provided in the embodiments of the present disclosure. The display panel includes a plurality of first sub-pixels and a plurality of second sub-pixels on the base substrate. Each of the plurality of first sub-pixels and the plurality of second sub-pixels includes a pixel circuit layer and a light-emitting unit layer that are stacked in a direction away from the base substrate in sequence. The display panel further includes a pixel definition layer and a plurality of light-shielding layers that are disposed on a side of the light-emitting unit layer. As the light shield portions of the light-shielding layers are overlapped with the pixel definition portions defining the first sub-pixels, the plurality of first sub-pixels and the plurality of second sub-pixels are flexibly lightened up to adjust the light emitting angle to switch between peep-proof and sharing. In addition, as the switch circuits controlling the light-emitting element and the drive circuit to be on and off in the plurality of first sub-pixels and the plurality of second sub-pixels are different, the plurality of first sub-pixels and the plurality of second sub-pixels are separately controlled to emit light, such that the peep-proof angle is flexibly adjusted, and the peep-proof flexibility is improved.

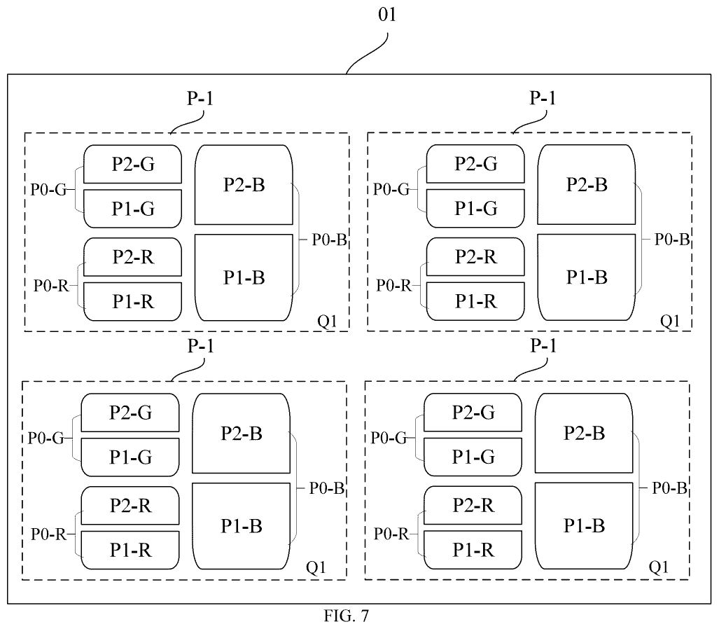

In an alternative implementation, on the basis of FIG. 1, it can be seen in conjunction with FIG. 6 and FIG. 7 that the display panel according to the embodiments of the present disclosure includes a plurality of first pixels P-1 in the plurality of pixel sub-regions Q1, each of the plurality of first pixels P-1 includes a plurality of sub-pixels P0 with different colors, and each sub-pixel P0 includes a first sub-pixel P1 and a second sub-pixel P2 that are in one-to-one correspondence. It can be seen on this basis that a number of the plurality of pixel sub-regions Q1 is equal to a number of the plurality of first pixels P-1, and the plurality of first pixels P-1 are in one-to-one correspondence to the plurality of pixel sub-regions Q1. That is, each sub-pixel in a pixel is divided into two portions by cutting, and the two portions are determined as the first sub-pixel P1 and the second sub-pixel P2 that are in one-to-one correspondence. It should be noted that the anode Anode of the sub-pixel is divided into two portions.

Illustratively, referring to FIG. 6 and FIG. 7, each shown first pixel P-1 includes three sub-pixels P0 with different colors, that is, a red sub-pixel P0-R, a green sub-pixel P0-G, and a blue sub-pixel P0-B. The red sub-pixel P0-R includes a first red sub-pixel P1-R and a second red sub-pixel P2-R, the green sub-pixel P0-G includes a first green sub-pixel P1-G and a second green sub-pixel P2-G, and THE blue sub-pixel P0-B includes a first blue sub-pixel P1-B and a second blue sub-pixel P2-B. FIG. 6 and FIG. 7 differ in the shape of the pixel. The first pixel P-1 shown in FIG. 6 is in an oval shape, and the first pixel P-1 shown in FIG. 7 is in a rectangular shape. The shapes herein are illustrative.

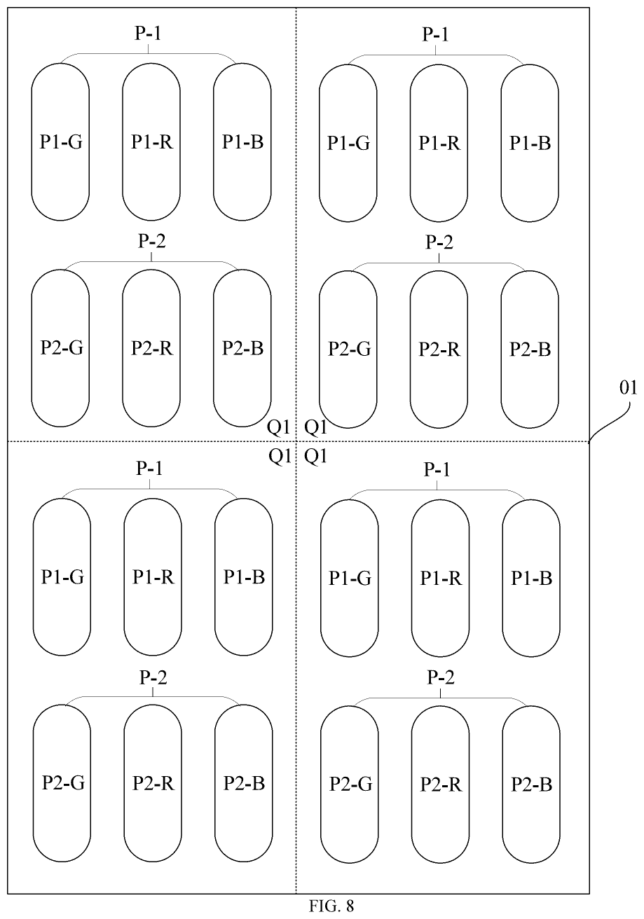

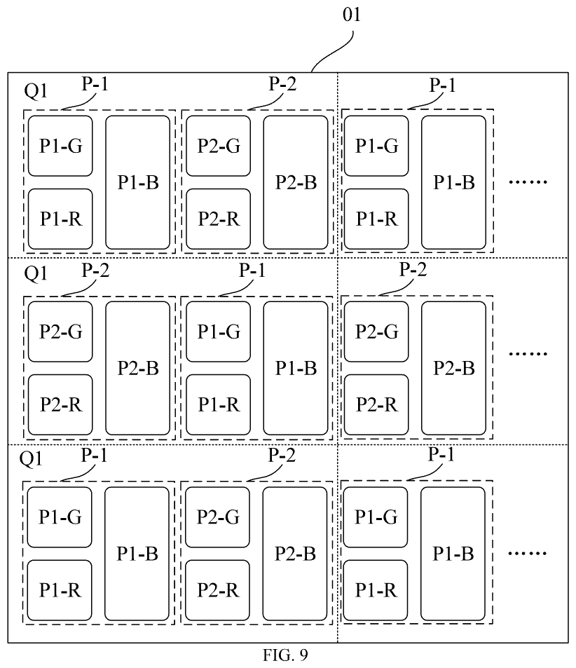

In an alternative implementation, it can be seen in conjunction with FIG. 8 and FIG. 9 that the display panel according to the embodiments of the present disclosure includes a plurality of first pixels P-1 and a plurality of second pixels P-2 in the plurality of pixel sub-regions Q1, each of the plurality of first pixels P-1 includes a plurality of first sub-pixels P1 with different colors, and each of the plurality of second pixels P-2 includes a plurality of second sub-pixels P2 that are in one-to-one correspondence to the plurality of first sub-pixels P1 with different colors. It can be seen on this basis that a number of the plurality of pixel sub-regions Q1 is equal to a sum of a number of the plurality of first pixels P-1 and a number of the plurality of second sub-pixels P-2. That is, a set of two pixels are disposed to switch between peep-proof and sharing, rather than each sub-pixel in the pixel is divided into two portions to switch between peep-proof and sharing. It should be noted that in the case that a size of the display panel is fixed, compared with the solutions shown in FIG. 6 and FIG. 7, the resolution is reduced the solutions shown in FIG. 8 and FIG. 9, which is not conducive to high-resolution design.

Illustratively, referring to FIG. 8 and FIG. 9, each shown first pixel P-1 includes three first sub-pixels P1 with different colors, that is, a red first sub-pixel P1-R, a green first sub-pixel P1-G, and a blue first sub-pixel P1-B. Each shown second pixel P-2 includes three second sub-pixels P2 with different colors, that is, a red second sub-pixel P2-R, a green second sub-pixel P2-G, and a blue second sub-pixel P2-B. FIG. 8 and FIG. 9 differ in the shape of the pixel. The first pixel P-1 and the second sub-pixel P-2 shown in FIG. 8 is in the oval shape, which are the same as that shown in FIG. 6, and the first pixel P-1 and the second sub-pixel P-2 shown in FIG. 9 is in the rectangular shape, which are the same as that shown in FIG. 7. The shapes herein are illustrative.

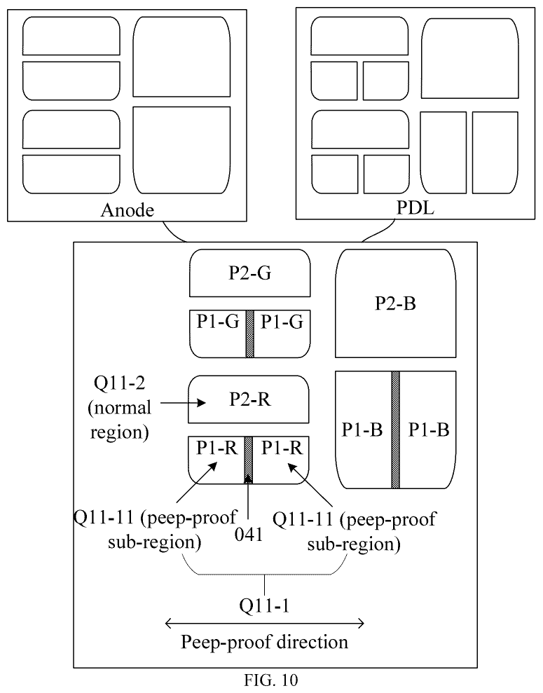

On the basis of FIG. 8, it can be seen referring to FIG. 10 that in the embodiments of the present disclosure, the first pixel unit region Q11-1 includes a plurality of pixel unit sub-regions Q11-11, also referred to as the peep-proof sub-regions, defined by the defining portions 041. Illustratively, in the display panel shown in FIG. 10, each first pixel unit region Q11-1 includes two pixel unit sub-regions Q11-11. By dividing the peep-proof region into more peep-proof sub-regions, the peep-proof angle is further flexibly controlled, and the peep-proof flexibility is improved.

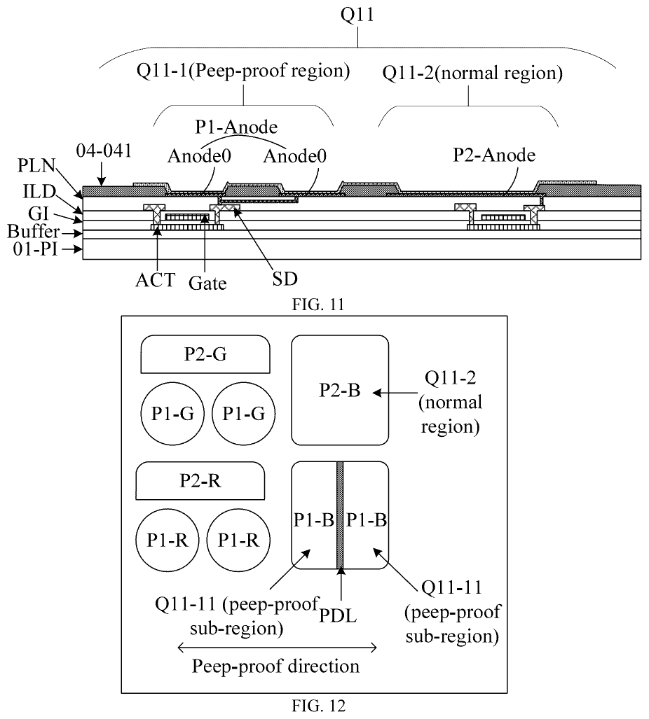

In addition, on the basis of FIG. 10, it can be seen referring to FIG. 11 that the anode Anode of first sub-pixel P1 in each first pixel unit region Q11-1 includes a plurality of anode portions Anode0 that are disposed in a plurality of pixel unit sub-regions Q11-1 and are coupled to each other. That is, the anodes Anode in each pixel unit sub-region Q11-11 in the first pixel unit region Q11-1 are shared, such that a number of required sub-pixels is reduced to facilitate high-resolution design. FIG. 10 further shows the film layer of the anode Anode and the film layer of the pixel definition layer PDL. Compared with the film layer of the anode Anode and the film layer of the pixel definition layer PDL, it can be seen that only the pixel definition layer PDL is divided into two portions to define the pixel unit sub-regions Q11-11, and the anode Anode belonging to a first pixel unit region Q11-1 are of an integrated structure. In some embodiments, the anodes Anode in each pixel unit sub-region Q11-11 in first the pixel unit region Q11-1 are not shared.

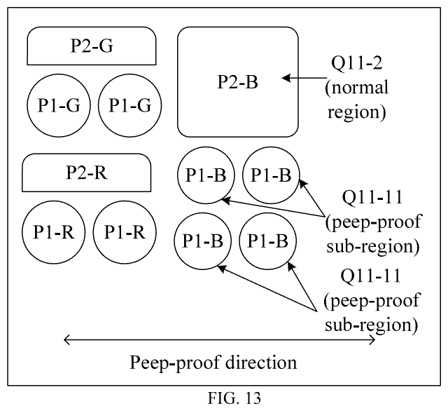

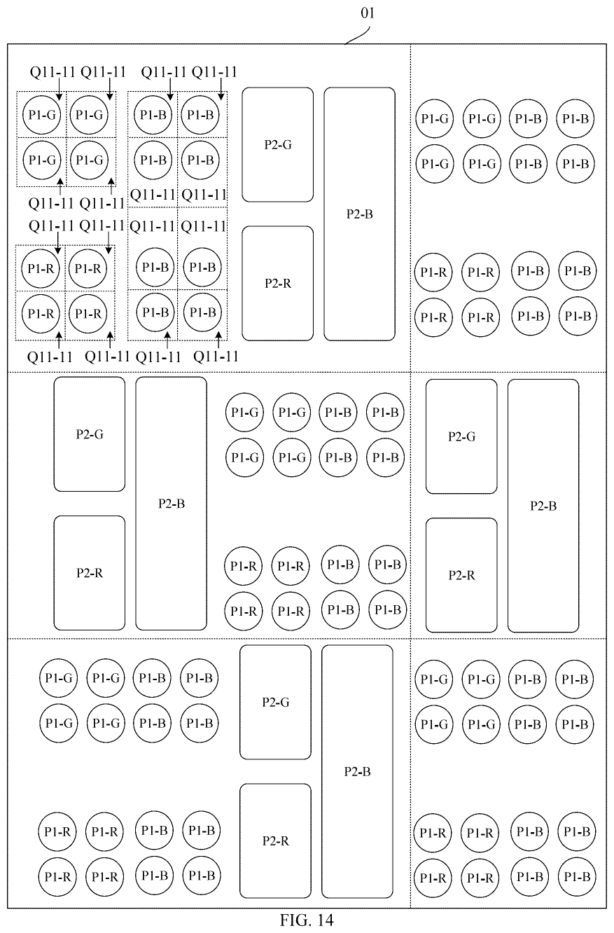

In some embodiments, it can be seen referring to FIG. 10 that the shape of the pixel unit sub-region Q11-11 in the first pixel unit region Q11-1 and the second pixel unit region Q11-2 are the same. Alternatively, referring to the layouts shown in FIG. 12, FIG. 13, and FIG. 14 shown in FIG. 9, the shape of the pixel unit sub-region Q11-11 in the first pixel unit region Q11-1 and the second pixel unit region Q11-2 are different.

Illustratively, in FIG. 12, the pixel unit sub-regions Q11-11 in the first pixel unit regions Q11-1 including the green first sub-pixel P1-G and the red first sub-pixel P1-R are in a circular shape, and the first pixel unit region Q11-1 including the blue first sub-pixel P1-B is a quadrilateral with rounded corners. In some embodiments, the pixel unit region Q11-1 is in an octagonal, trapezoidal, oval, or other shapes. FIG. 12, FIG. 13 and FIG. 14 differ in the number of the pixel unit sub-regions (that is, the peep-proof sub-regions) Q11-11. In FIG. 12, each first pixel unit region Q11-1 is divided into two peep-proof sub-regions. In FIG. 13, the first pixel unit regions Q11-1 including the green first sub-pixel P1-G and the red first sub-pixel P1-R each is divided into two peep-proof sub-regions, and the first pixel unit region Q11-1 including the blue first sub-pixel P1-B is divided into four peep-proof sub-regions. In FIG. 14, the first pixel unit regions Q11-1 including the green first sub-pixel P1-G and the red first sub-pixel P1-R each is divided into four peep-proof sub-regions, and the first pixel unit region Q11-1 including the blue first sub-pixel P1-B is divided into eight peep-proof sub-regions. It should be noted that the numbers and shapes of the peep-proof sub-regions are illustrative.

In some embodiments, as shown in FIG. 2, the display panel according to the embodiments of the present disclosure includes two light-shielding layers 06. In the embodiments of the present disclosure, a distance between the two light-shielding layers 06 is greater than 5 microns (μm).

In some embodiments, in conjunction with FIG. 10, FIG. 12, and FIG. 13, in the embodiments of the present disclosure, a length (diameter) of the peep-proof sub-region in a peep-proof direction shown in the drawings is less than 15 μm.

In some embodiments of the present disclosure, in the plurality of first sub-pixels P1 and the plurality of second sub-pixels P2 that are in one-to-one correspondence, an area of the light-emitting element 031 in each of the plurality of first sub-pixels P1 is less than an area of the light-emitting element 031 in each of the plurality of second sub-pixels P2. The area may refer to the area of the anode Anode. As such, a light-emitting area of the first sub-pixel P1 is less than a light-emitting area of the second sub-pixel P2 to ensure the display effect of the display panel in the sharing mode. In some embodiments, an area of the first pixel unit region Q11-1 is less than an area of the second pixel unit region Q11-2.

Illustratively, referring to FIG. 2, in the plurality of first sub-pixels P1 and the plurality of second sub-pixels P2 that are in one-to-one correspondence in the shown display panel, an area of the first sub-pixel P1 is equal to an area of the second sub-pixel P2. On the basis of FIG. 2, referring to FIG. 15, in the plurality of first sub-pixels P1 and the plurality of second sub-pixels P2 that are in one-to-one correspondence in the shown display panel, an area of the first sub-pixel P1 is less than an area of the second sub-pixel P2.

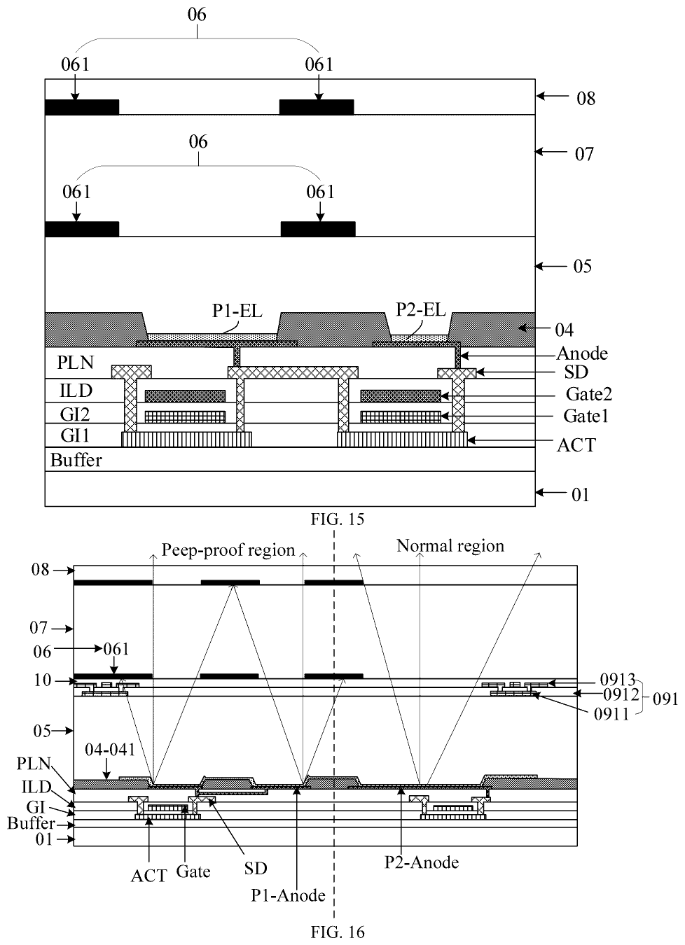

In some embodiments, referring to FIG. 2 and FIG. 15 and on the basis of FIG. 11, it can be seen from the structures of the two display panels shown in FIG. 16 and FIG. 17 that the display panel according to the embodiments of the present disclosure further includes:
a spacer layer 07 between each two adjacent layers of the plurality of light-shielding layers 06 and a first overcoat layer (OC) 08, that is, an OC1 layer, on a side, away from the base substrate 01, of the plurality of light-shielding layers 06. In some embodiments, the spacer layer 07 is formed by an ink-jet printing (IJP) process. Accordingly, the spacer layer 07 is also referred to as an IJP layer.

It can be further seen in conjunction with FIG. 16 and FIG. 17 that the display panel further includes a touch layer 09 and a second overcoat layer 10, that is, the OC2 layer, between the encapsulation layer 05 and the plurality of light-shielding layers 06 and stacked in the direction away from the base substrate 01 in sequence. The touch layer 09 is also referred to as a flexible multi-layer on cell (FMLOC) layer, and is configured to achieve the touch detection function.

The touch layer 09 includes a plurality of touch electrodes 091 that are spaced apart. Each of the plurality of touch electrodes 091 includes a first electrode layer 0911, an interlayer dielectric layer 0912, and a second electrode layer 0913 that are stacked in the direction away from the base substrate 01 in sequence, and an orthographic projection of each of the plurality of touch electrodes 091 on the base substrate 01 is overlapped with an orthographic projection of a portion, between two adjacent of the plurality of pixel unit regions Q11, of the pixel definition layer 04 on the base substrate 01. That is, in the embodiments of the present disclosure, as shown in FIG. 16 and FIG. 17, the touch trace is disposed on the pixel definition layer PDL side around the pixel, rather than inside the pixel, such that interference between the touch and display signals is avoided, the traces are simplified, and the cost is saved.

It should be noted that the structures shown in FIG. 16 and FIG. 17 differ in that in the display panel shown in FIG. 16, the orthographic projection of each of the light shield portions 061 in the two light-shielding layers 06 on the base substrate 01 is only overlapped with the orthographic projection of one of the pixel definition portions 041 defining the first sub-pixels P1 on the base substrate 01, and in the display panel shown in FIG. 17, the orthographic projection of each of the light shield portions 061 in the light-shielding layer 06 close to the base substrate 01 on the base substrate 01 is also overlapped with the orthographic projection of one of the pixel definition portions 041 defining the first sub-pixels P1 on the base substrate 01. In addition, FIG. 16 and FIG. 17 further show schematic diagrams of propagation of light emitted from sub-pixels in the peep-proof region and the normal region.

In addition, it can be seen referring to FIG. 17 that the display panel further includes a color filter portion CF between each two adjacent of the plurality of light shield portions 061 in at least one layer of the plurality of light-shielding layers 06. The light shield portion 061 and the color filter portion CF are combined as the light-shielding layer 06. It should be noted that by disposing the color filter portion CF, the color filtering effect is achieved, and the display effect is great. Alternatively, in some embodiments, in conjunction with FIG. 15 and FIG. 16, the light-shielding layer 06 includes black matrix layer (BM) or a black pixel definition layer PDL, as long as achieving the light-shielding effect. The black pixel definition layer PDL and the pixel definition layer 04 are made of the same material, for example, acrylic or polyimide. The OC1 layer and the OC2 layer are made of acrylic.

In some embodiments, it can be seen referring to FIG. 2 and FIG. 15 that the pixel circuit layer 02 further includes an active layer ACT, a first gate insulator layer GI1, a first gate metal layer Gate1, a second gate insulator layer GI2, a second gate metal layer Gate2, an interlayer dielectric layer ILD, and a source and drain metal layer SD that are stacked in the direction away from the base substrate 01 in sequence. Alternatively, it can be seen referring to FIG. 2 and FIG. 15 that the pixel circuit layer 02 only includes a gate metal layer Gate (for example, the first gate metal layer Gate1) and does not include the second gate metal layer Gate2, and correspondingly, only includes a gate insulator layer GI (for example, the first gate insulator layer GI1) and does not include the second gate insulator layer GI2. The source and drain metal layer SD is lapped with the active 1 layer ACT and is coupled to the anode Anode. In addition, it can be seen referring to FIG. 2 and FIG. 15 to FIG. 17 that the display panel further includes a buffer layer Buffer between the base substrate 01 and the active layer ACT, and a planarization layer PLN between the source and drain metal layer SD and the anode Anode.

In some embodiments, the base substrate 01 is made of the flexible material, for example, polyimide (PI). Accordingly, the base substrate 01 is also referred to as the PI layer. The active layer ACT is made of P—Si.

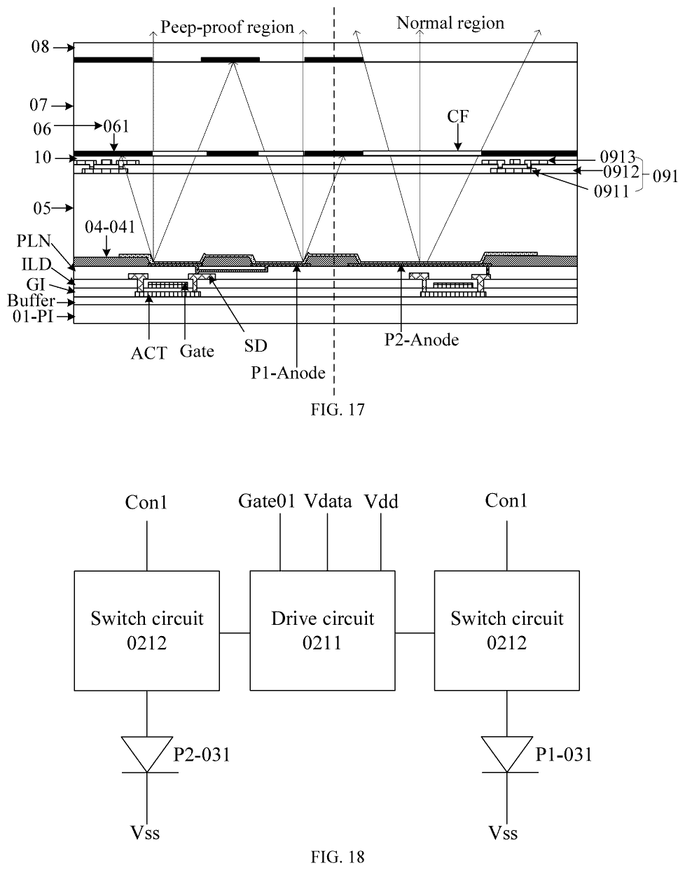

In some embodiments, it can be seen referring to the pixel circuit shown in FIG. 18 that in the plurality of first sub-pixels P1 and the plurality of second sub-pixels P2 that are in one-to-one correspondence in the embodiments of the present disclosure, the drive circuit 0211 of each of the sub-pixels is coupled to a gate signal terminal Gate01, a data signal terminal Vdata, and a drive power terminal Vdd and is configured to generate the drive signal based on a gate drive signal supplied by the gate signal terminal Gate01, a data signal supplied by the data signal terminal Vdata, and a drive power signal supplied by the drive power terminal Vdd.

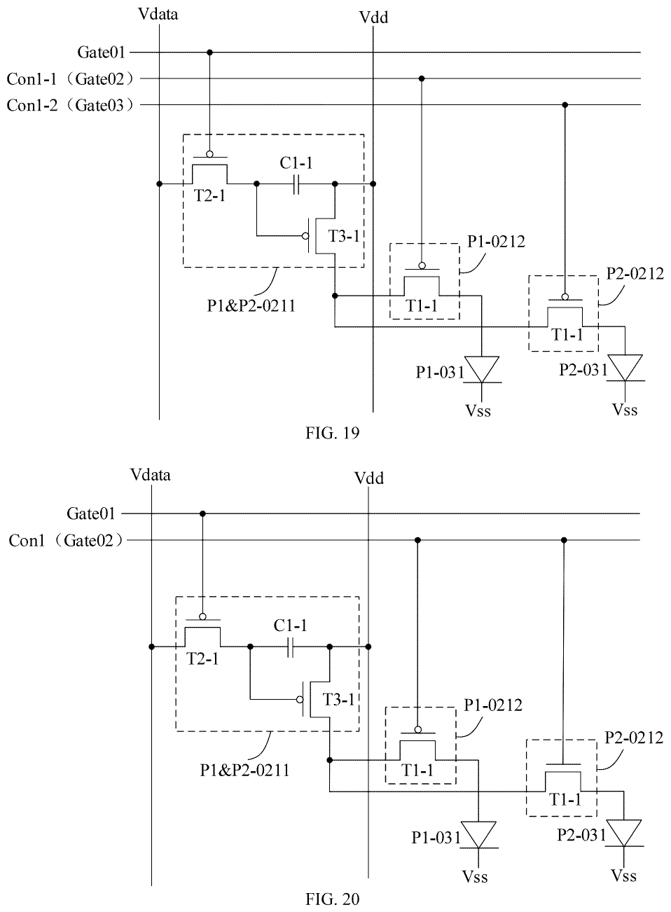

In an alternative implementation, on the basis of FIG. 18, it can be seen referring to the pixel circuit shown in FIG. 19 that the switch circuit 0212 of each of the sub-pixels in the embodiments of the present disclosure includes a first switch transistor T1-1.

A gate electrode of the first switch transistor T1-1 is coupled to the switch control terminal Con1, a first electrode of the first switch transistor T1-1 is coupled to the drive circuit 0211, and a second electrode of the first switch transistor T1-1 is coupled to the light-emitting element 031.

On this basis, it can be seen referring to FIG. 19 that the drive circuit 0211 of each of the sub-pixels further includes a first data write transistor T2-1, a first drive transistor T3-1, and a first storage capacitor C1-1.

A gate electrode of the first data write transistor T2-1 is coupled to the gate signal terminal Gate01, a first electrode of the first data write transistor T2-1 is coupled to the data signal terminal Vdata, and a second electrode of the first data write transistor T2-1 is coupled to a first terminal of the first storage capacitor C1-1. A second terminal of the first storage capacitor C1-1 is coupled to the drive power terminal Vdd. A gate electrode of the first drive transistor T3-1 is coupled to the first terminal of the first storage capacitor, a first electrode of the first drive transistor T3-1 is coupled to the drive power terminal Vdd, and a second electrode of the first drive transistor T3-1 is coupled to the first electrode of the first switch transistor T1-1.

In the case that the gate signal terminal Gate01 supplies the gate drive signal at the valid potential, the first data write transistor T2-1 is turned on, and the data signal supplied by the data signal terminal Vdata is transmitted to the first terminal of the first storage capacitor C1-1 through the turned on first data write transistor T2-1, and is then transmitted to the gate electrode of the first drive transistor T3-1 under coupling of the first storage capacitor C1-1. The first drive transistor T3-1 generates the drive signal based on the received data signal and the drive power signal supplied by the drive power terminal Vdd, and transmits the drive signal to the first electrode of the first switch transistor T1-1. In the case that the switch control terminal Con1 supplies the switch control signal at the valid potential, the first switch transistor T1-1 is turned on, and the drive signal transmitted to the first electrode of the first switch transistor T1-1 is transmitted to the second electrode of the first switch transistor T1-1 through the turned on first switch transistor T1-1, that is, transmitted to the light-emitting element 031, such that the light-emitting element 031 is driven to emit light.

It should be noted that for separate control, in different switch circuits 0212 in the pixel circuits 021 in the plurality of first sub-pixels P1 and the plurality of second sub-pixels P2 that are in one-to-one correspondence, types of switch transistors are the same (for example, are the P-type transistors shown in FIG. 19), and the different switch circuits 0212 (that is, different first switch transistors T1-1) are coupled to different switch control terminals Con1. In FIG. 19, the switch control terminal Con1 coupled to the switch circuit 0212 in the first sub-pixel P1 is marked as Con1-1 and the switch control terminal Con1 coupled to the switch circuit 0212 in the second sub-pixel P2 is marked as Con1-1 for distinguishing. Alternatively, in different switch circuits 0212 in the pixel circuits 021 in the plurality of first sub-pixels P1 and the plurality of second sub-pixels P2 that are in one-to-one correspondence, types of switch transistors are different (for example, are a P-type transistor and a N-type transistor shown in FIG. 20), and the different switch circuits 0212 (that is, different first switch transistors T1-1) are coupled to a same switch control terminal Con1. In addition, in the pixel circuits shown in FIG. 19 and FIG. 20, the first data write transistor T2-1 and the first drive transistor T3-1 are P-type transistors.

It should be further noted that for the structures shown in FIG. 19 and FIG. 20, the switch control terminal Con1 is a signal terminal that has the same function as the gate signal terminal Gate01 coupled to the first data write transistor T2-1, and is also referred to as the gate signal terminal. The switch control terminals Con1-1 and Con1-2 coupled to different first switch transistors T1-1 are also marked as Gate02 and Gate03 in FIG. 19, and the switch control terminals Con1 coupled to different first switch transistors T1-1 are also marked as Gate02 in FIG. 20.

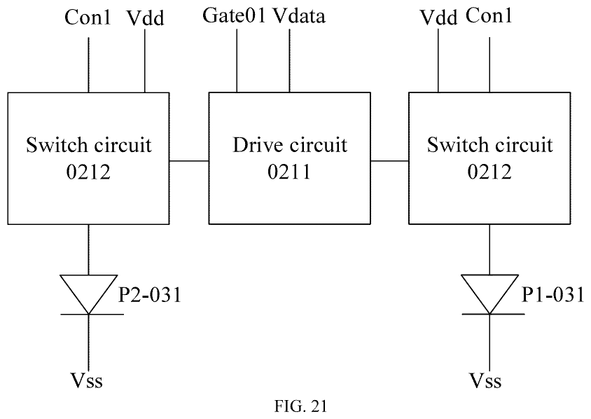

In an alternative implementation, it can be seen referring to the pixel circuit shown in FIG. 21 that in the plurality of first sub-pixels P1 and the plurality of second sub-pixels P2 that are in one-to-one correspondence, the switch circuit 0212 of at least one sub-pixel is coupled to the drive power terminal Vdd and the drive circuit 0211, and is configured to control, based on the switch control signal, the drive power terminal Vdd and the drive circuit 0211 to be on and off.

For example, in the case that a potential of the switch control signal is the valid potential, the switch circuit 0212 controls the drive power terminal Vdd and the drive circuit 0211 to be on; and in the case that the potential of the switch control signal is the invalid potential, the switch circuit 0212 controls the drive power terminal Vdd and the drive circuit 0211 to be disconnected.

On the basis of FIG. 21, it can be seen referring to the pixel circuits shown in FIG. 22 to FIG. 24 that for the structure shown in FIG. 21, the switch circuit 0212 of the at least one sub-pixel further includes a second switch transistor T1-2.

A gate electrode of the second switch transistor T1-2 is coupled to the switch control terminal Con1, a first electrode of the second switch transistor T1-2 is coupled to the drive power terminal Vdd, and a second electrode of the second switch transistor T1-2 is coupled to the drive circuit 0211.

The drive circuit 0211 of each of the sub-pixels includes a second data write transistor T2-2, a second drive transistor T3-2, a compensation transistor T4, and a second storage capacitor C1-2.

A gate electrode of the second data write transistor T2-2 and a gate electrode of the compensation transistor T4 are coupled to the gate signal terminal Gate01, a first electrode of the second data write transistor T2-2 is coupled to the data signal terminal Vdata, and a second electrode of the second data write transistor T2-2 is coupled to a first electrode of the second drive transistor T3-2. A first electrode of the compensation transistor T4 is coupled to a second electrode of the second drive transistor T3-2, and a second electrode of the compensation transistor T4 is coupled to a gate electrode of the second drive transistor T3-2. A first electrode of the second drive transistor T3-2 is coupled to the second electrode of the second switch transistor T1-2. A first terminal of the second storage capacitor C1-2 is coupled to the gate electrode of the second drive transistor T3-2, and a second terminal of the second storage capacitor C1-2 is coupled to the drive power terminal Vdd.

In the case that the gate signal terminal Gate01 supplies the gate drive signal at the valid potential, the second data write transistor T2-2 and the compensation transistor T4 are turned on, and the data signal supplied by the data signal terminal Vdata is written to the first electrode of the second drive transistor T3-2 through the turned on second data write transistor T2-2. In the case that the second drive transistor T3-2 is turned on, the data signal is transmitted to the gate electrode of the second drive transistor T3-2 through the turned on second drive transistor T3-2 and the turned on compensation transistor T4, and the second storage capacitor C1-2 stores the potential of the gate electrode of the second drive transistor T3-2. In the case that the switch control terminal Con1 supplies the switch control signal at the valid potential, the first switch transistor T1-1 and the second switch transistor T1-2 are turned on, and the drive power signal supplied by the drive power terminal Vdd is transmitted to the first electrode of the second drive transistor T3-2. The second drive transistor T3-2 generates the drive signal based on the received data signal and the drive power signal supplied by the drive power terminal Vdd, and transmits the drive signal to the light-emitting element 031 through the turned on first switch transistor T1-1, such that the light-emitting element 031 is driven to emit light.

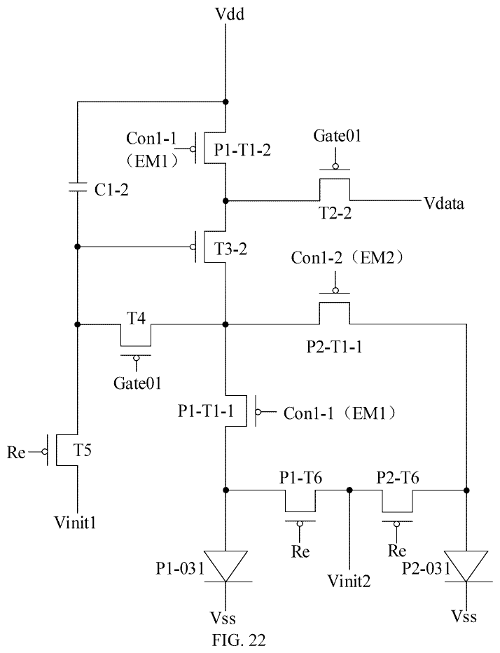

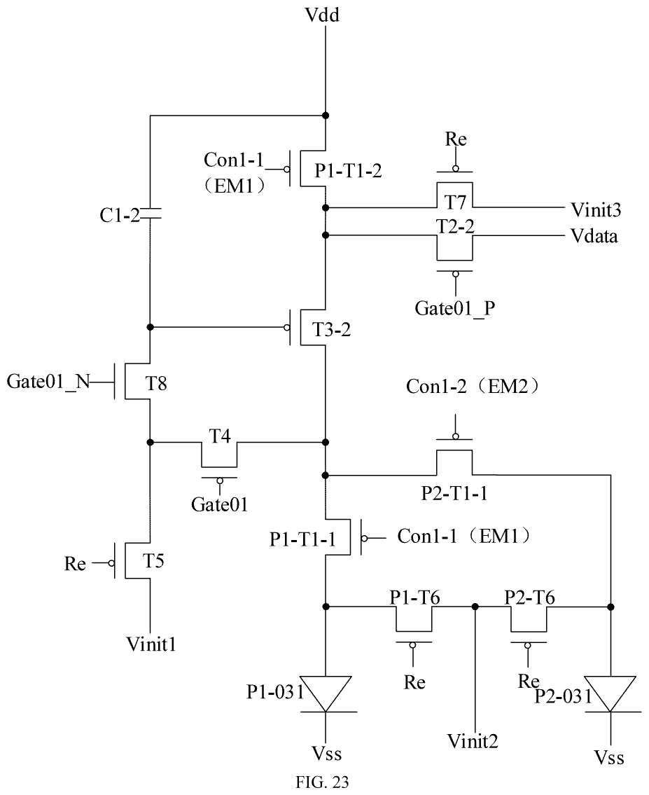

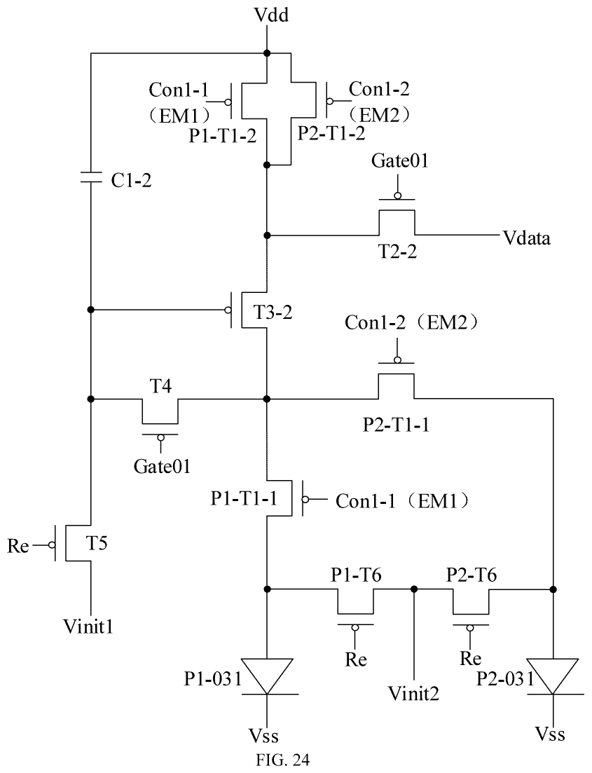

It should be noted that FIG. 22 to FIG. 24 differ in that the transistors in the pixel circuits are P-type transistors in FIG. 22 and FIG. 24, and the pixel circuit includes the P-type transistor and the N-type transistor in FIG. 23, which is applicable to a low-temperature poly-silicon oxide (LTPO) display scenario. In addition, the switch circuits 0212 in the first sub-pixels P1 include the first switch transistors T1-1 and the second switch transistors T1-2 in FIG. 22 and FIG. 23, and the switch circuits 0212 in the first sub-pixel P1 and the second sub-pixel P2 include the first switch transistors T1-1 and the second switch transistors T1-2 in FIG. 24.

In some embodiments, it can be seen referring to FIG. 22 to FIG. 24 that the pixel circuit in the alternative implementation further includes a first reset transistor T5 and a sixth reset transistor T6. The first sub-pixel P1 and the second sub-pixel P2 share the first reset transistor T5 and include different sixth reset transistors T6. A gate electrode of the first reset transistor T5 and a gate electrode of the sixth reset transistor T6 are coupled to a reset signal terminal Re, a first electrode of the first reset transistor T5 is coupled to a first initial power terminal Vinit1, a second electrode of the first reset transistor T5 is coupled to the gate electrode of the second drive transistor T3-2, a first electrode of the sixth reset transistor T6 is coupled to a second initial power terminal Vinit2, a second electrode of the sixth reset transistor T6 is coupled to the anode of the light-emitting element 031. In the case that the reset signal terminal Re supplies a reset signal at the valid potential, the first reset transistor T5 and the sixth reset transistor T6 are turned on, a first initial power signal supplied by the first initial power terminal Vinit1 is transmitted to the gate electrode of the second drive transistor T3-2 through the turned on first reset transistor T5 to rest the gate electrode of the second drive transistor T3-2, and a second initial power signal supplied by the second initial power terminal Vinit2 is transmitted to the anode of the light-emitting element 031 through the turned on sixth reset transistor T6 to rest the gate electrode of the anode of the light-emitting element 031.

In addition, for LTPO display products, the pixel circuit further includes a seventh reset transistor T7 and a switch control transistor T8. A gate electrode of the seventh reset transistor T7 is coupled to the reset signal terminal Re, a first electrode of the seventh reset transistor T7 is coupled to a third initial power terminal Vinit3, and a second electrode of the seventh reset transistor T7 is coupled to the first electrode of the second drive transistor T3-2. In the case that the reset signal terminal Re supplies the reset signal at the valid potential, the seventh reset transistor T7 is turned on, and a third initial power signal supplied by the third initial power terminal Vinit3 is transmitted to the first electrode of the second drive transistor T3-2 through the turned on seventh reset transistor T7 to reset the first electrode of the second drive transistor T3-2. A gate electrode of the switch control transistor T8 is coupled to the gate signal terminal Gate01, a first electrode of the switch control transistor T8 is coupled to the first electrode of the first reset transistor T5 and the second electrode of the compensation transistor T4, and a second electrode of the switch control transistor T8 is coupled to the gate electrode of the second drive transistor T3-2. In the case that the gate signal terminal Gate01 supplies the gate drive signal at the valid potential, the switch control transistor T8 is turned on, such that the first electrode of the first reset transistor T5 and the second electrode of the compensation transistor T4 are conducted to the gate electrode of the second drive transistor T3-2 to control the potential of the gate electrode of the second drive transistor T3-2.

In some embodiments, in FIG. 23, the seventh reset transistor T7 is a P-type transistor, and the switch control transistor T8 is a N-type transistor. The gate signal terminal Gate01 coupled to the N-type switch control transistor T8 is marked as Gate01_N, and the gate signal terminals Gate01 coupled to the P-type second data write transistor T2-2 and the compensation transistor T4 are marked as Gate01_P for distinguishing. The first reset transistor T5 and the sixth reset transistor T6 shown in FIG. 22 to FIG. 24 are P-type transistors.

It should be noted that the above description merely illustrates the on state of the transistors, and the transistors are turned off in the case that the gates of the transistors receives a signal at the invalid potential. In addition, for the structure shown in FIG. 22 to FIG. 24, the switch control terminal Con1 is also referred to as the light-emitting control terminal. In the drawings, the switch control terminals Con1-1 and Con1-2 coupled to different first switch transistors T1-1 and second switch transistors T1-2 are also marked as EM1 and EM2 respectively. In addition, the above description is only illustration of the pixel circuit.

In some embodiments, transistors in the embodiments of the present disclosure can be field-effect transistors or other devices with similar characteristics. According to the roles in the circuit, the transistors in the embodiments of the present disclosure are mainly switch transistors. As a source electrode and a drain electrode of the switch transistor used herein are symmetrical, the source electrode and the drain electrode are exchangeable. In the embodiments of the present disclosure, the source electrode is referred to as a first electrode, and the drain electrode is referred to as a second electrode. According to the shape in the accompanying drawings, a middle terminal of the transistor is specified as a gate, a signal input terminal is the source electrode, and the signal output terminal is the drain electrode. In addition, the switch transistor in the embodiments of the present disclosure includes a P-type switch transistor or an N-type switch transistor. The P-type switch transistor is turned on in the case that the gate is at a low level and turned off in the case that the gate is at a high level, and the N-type switch transistor is turned on in the case that the gate is at a high level and turned off in the case that the gate is at a low level. In addition, a plurality of signals in the embodiments of the present disclosure correspond to a first level and a second level. The first level and the second level only represent that the level of the signal has two state, and do not represent that the first level or the second level herein has a specific value.

In summary, a display panel is provided in the embodiments of the present disclosure. The display panel includes a plurality of first sub-pixels and a plurality of second sub-pixels on the base substrate. Each of the plurality of first sub-pixels and the plurality of second sub-pixels includes a pixel circuit layer and a light-emitting unit layer that are stacked in a direction away from the base substrate in sequence. The display panel further includes a pixel definition layer and a plurality of light-shielding layers that are disposed on a side of the light-emitting unit layer. As the light shield portions of the light-shielding layers are overlapped with the pixel definition portions defining the first sub-pixels, the plurality of first sub-pixels and the plurality of second sub-pixels are flexibly lightened up to adjust the light emitting angle to switch between peep-proof and sharing. In addition, as the switch circuits controlling the light-emitting element and the drive circuit to be on and off in the plurality of first sub-pixels and the plurality of second sub-pixels are different, the plurality of first sub-pixels and the plurality of second sub-pixels are separately controlled to emit light, such that the peep-proof angle is flexibly adjusted, and the peep-proof flexibility is improved.

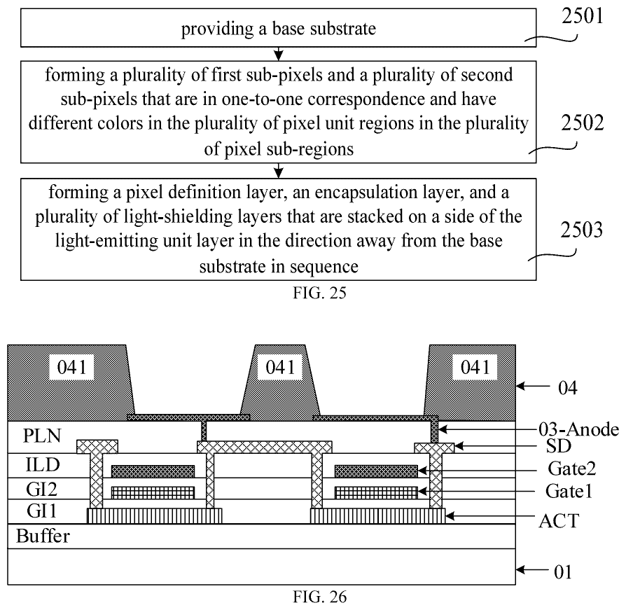

Some embodiments of the present disclosure further provide a method for manufacturing a display panel. The method is applicable to manufacturing the display panel in the above embodiments. As shown in FIG. 25, the method includes the following processes.

In S2501, a base substrate is provided.

Referring to FIG. 1, the provided base substrate 01 includes a plurality of pixel sub-regions Q1. Each of the plurality of pixel sub-regions Q1 includes a plurality of pixel unit regions Q11, and each of the plurality of pixel unit regions Q11 including a first pixel unit region Q11-1 and a second pixel unit region Q11-2.

In S2502, a plurality of first sub-pixels and a plurality of second sub-pixels that are in one-to-one correspondence are formed in different colors in the plurality of pixel unit regions in the plurality of pixel sub-regions.

Referring to FIG. 1, the formed plurality of first sub-pixels P1 are disposed in the first pixel unit region Q11-1, and the plurality of second sub-pixels P2 are disposed in the second pixel unit region Q11-2. Referring to FIG. 2, the formed first sub-pixel P1 and the second sub-pixel P2 each includes a pixel circuit layer 02 and a light-emitting unit layer 03 that are stacked in a direction away from the base substrate 01 in sequence. Referring to FIG. 5, the pixel circuit layer 02 is configured to form a pixel circuit 021, and the light-emitting unit layer 03 is configured to form a light-emitting element 031.

In S2503, a pixel definition layer, an encapsulation layer, and a plurality of light-shielding layers that are stacked in the direction away from the base substrate in sequence are formed on a side of the light-emitting unit layer.

Referring to FIG. 2, the formed pixel definition layer 04 includes a plurality of openings 04K and a plurality of pixel definition portions 041 surrounding the plurality of openings 04K, light-emitting unit layers 03 of any adjacent two sub-pixels in the plurality of first sub-pixels P1 and the plurality of second sub-pixels P2 are disposed in one of the plurality of openings 04K and defined by one of the plurality of pixel definition portions 041. The plurality of light-shielding layers 06 include a plurality of light shield portions 061 that are spaced apart, and an orthographic projection of each of the plurality of light shield portions 061 on the base substrate 01 is overlapped with an orthographic projection of one of the plurality of pixel definition portions 041 defining the plurality of first sub-pixels P1 on the base substrate 01.

Referring to FIG. 5, the formed pixel circuit includes a drive circuit 0211 and a switch circuit 0212, and pixel circuits 021 in the plurality of first sub-pixels P1 and the plurality of second sub-pixels P2 that are in one-to-one correspondence include different switch circuits 0212 and share a same drive circuit 0211.

The switch circuit 0212 is coupled to a switch control terminal Con1, the drive circuit 0211, and the light-emitting element 031, and is configured to control, based on a switch control signal supplied by the switch control terminal Con1, the drive circuit 0211 and the light-emitting element 031 to be on and off, and the drive circuit 0211 is configured to generate a drive signal for driving the light-emitting element 031 to emit light.

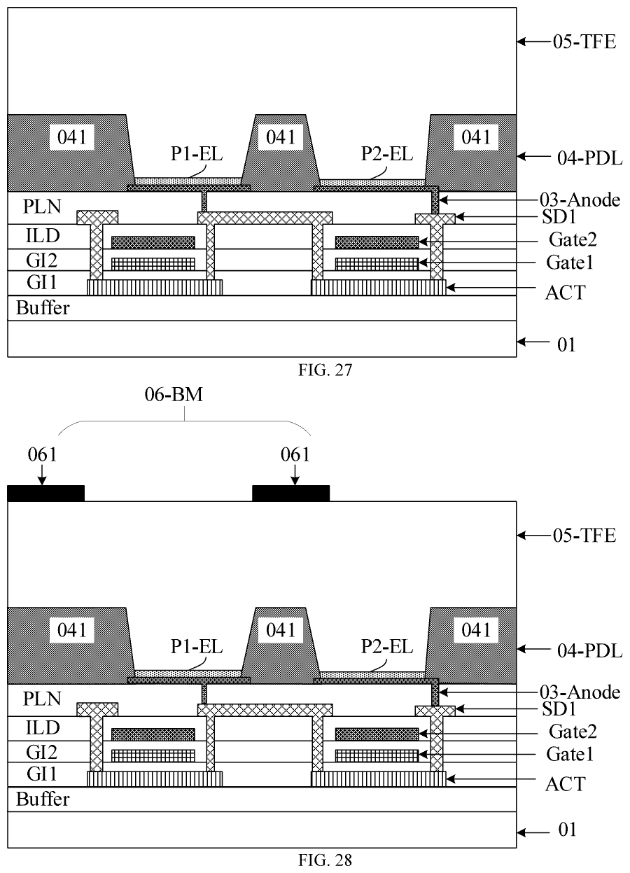

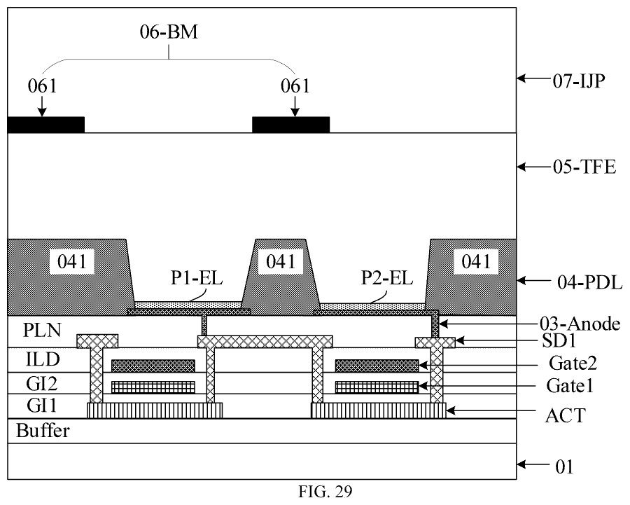

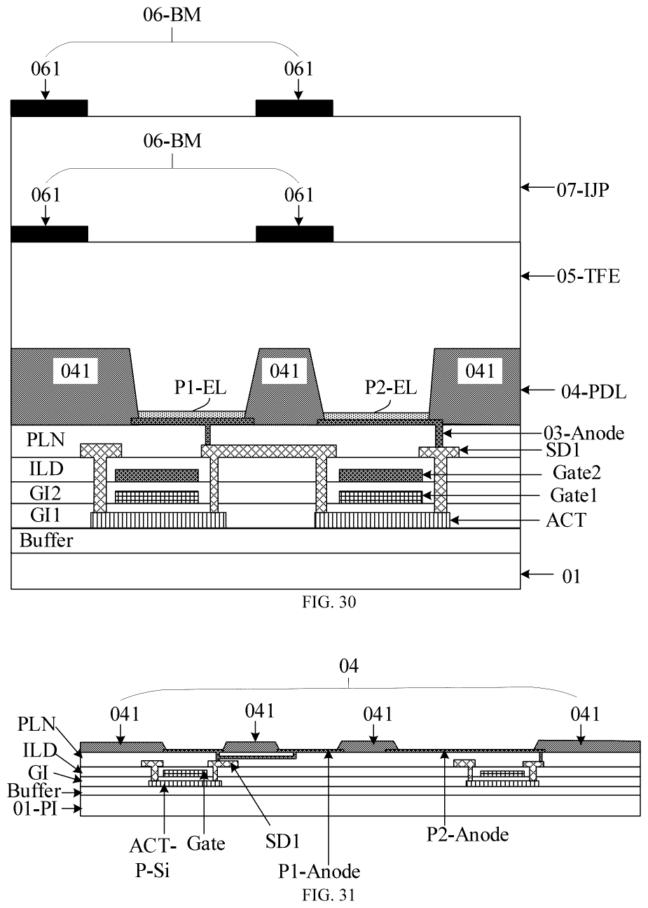

In an alternative implementation, using the display panel shown in FIG. 2 as an example, processes of the manufacturing method are illustrated as follows.
a. In conjunction with FIG. 26, a base substrate 01 is first provided, and a buffer later Buffer, an active layer ACT, a first gate insulator layer GI1, a first gate metal layer Gate1, a second gate insulator layer GI2, a second gate metal layer Gate2, an interlayer dielectric layer ILD, a source and drain metal layer SD, a planarization layer PLN, a light-emitting element 031 (FIG. 26 only shows the anode Anode of the light-emitting element 031), and a pixel definition layer 04 that are stacked in the direction away from the base substrate 01 in sequence are formed on a side of the base substrate 01. The pixel definition portion 041 in the pixel definition layer 04 defines the anode Anode in adjacent sub-pixels. That is, the above layers are manufactured by a backplane process in sequence. The formed active layer ACT, the first gate insulator layer GI1, the first gate metal layer Gate1, the second gate insulator layer GI2, the second gate metal layer Gate2, the interlayer dielectric layer ILD, and the source and drain metal layer SD are organized as the pixel circuit layer 02. The source and drain metal layer SD is lapped with the active layer ACT over a via penetrating the interlayer dielectric layer ILD, the second gate insulator layer GI2, and the first gate insulator layer GI1. In some embodiments, the base substrate 01 is a PI substrate, and the active layer ACT is a P—Si layer.
b. In conjunction with FIG. 27, upon the process a, the encapsulating process is performed. An encapsulation layer 05, or a thin film encapsulation (TFE), is formed on a side, away from the base substrate 01, of the pixel definition layer 04.
c. In conjunction with FIG. 28, upon the process b, a first light-shielding layer 06 is formed on a side, away from the base substrate 01, of the encapsulation layer 05, and the formed first light-shielding layer 06 includes a plurality of light shield portions 061 that are spaced apart, and the light shield portions 061 are at least overlapped with the pixel definition portions 041 defining the first sub-pixels P1 to limit the light emitting angle to achieve the peep-proof function. In addition, FIG. 27 illustratively shows the light-emitting layer EL.
d. In conjunction with FIG. 29, upon the process c, a spacer layer 07, that is, an IJP layer, is formed on a side, away from the first light-shielding layer 06 by the IJP process. That is, the IJP film manufacturing is performed.
e. In conjunction with FIG. 30, upon the process d, a second light-shielding layer 06 is formed on a side, away from the base substrate 01, of the IJP layer, and the formed second light-shielding layer 06 includes a plurality of light shield portions 061 that are spaced apart, and the light shield portions 061 are at least overlapped with the pixel definition portions 041 defining the first sub-pixels P1 to limit the light emitting angle to achieve the peep-proof function. In addition, FIG. 27 illustratively shows the light-emitting layer EL. The plurality of light-shielding layers 06 are disposed to limit the light emitting angle and reliably control the peep-proof angle. In some embodiments, the first light-shielding layer 06 and the second light-shielding layer 06 each is a black BM or a black PDL. In some embodiments, the display panel further includes a color filter portion CF, that is, a COE structure, between adjacent light shield portions 061.

Eventually, upon the process e, a first coating layer 08, also referred to as an OC1 layer, is disposed on a side, away from the base substrate 01, of the second light-shielding layer 06. That is, the OC1 layer is manufactured. In some embodiments, the IJP layer is also referred to as the OC layer, that is, the IJP layer and the OC layer are made of the same material.

In an alternative implementation, using the display panel shown in FIG. 16 as an example, processes of the manufacturing method are illustrated as follows.
f. In conjunction with FIG. 31, a base substrate 01 is first provided, and a buffer later Buffer, an active layer ACT, a gate insulator layer GI, a gate metal layer Gate, an interlayer dielectric layer ILD, a source and drain metal layer SD, a planarization layer PLN, a light-emitting element 031 (FIG. 31 only shows the anode Anode of the light-emitting element 031), and a pixel definition layer 04 that are stacked in the direction away from the base substrate 01 in sequence are formed on a side of the base substrate 01. The pixel definition portion 041 in the pixel definition layer 04 defines the anode Anode in adjacent sub-pixels. That is, the above layers are manufactured by a backplane process in sequence. The formed active layer ACT, the gate insulator layer GI, the gate metal layer Gate, the interlayer dielectric layer ILD, and the source and drain metal layer SD are organized as the pixel circuit layer 02. The source and drain metal layer SD is lapped with the active layer ACT over a via penetrating the interlayer dielectric layer ILD the gate insulator layer GI. In some embodiments, the base substrate 01 is a PI flexible substrate, and the active layer ACT is a P—Si layer.

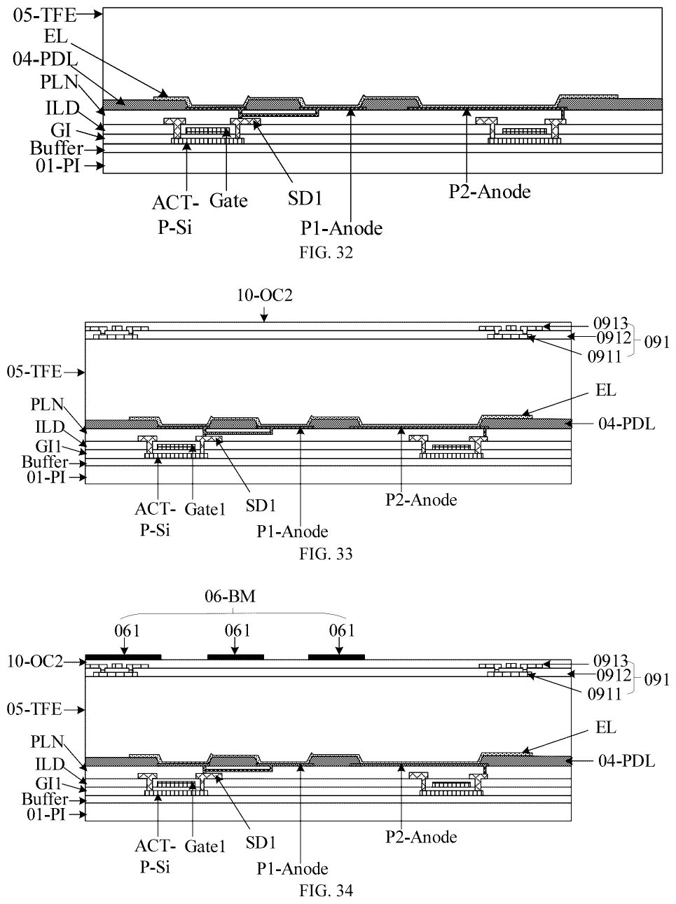

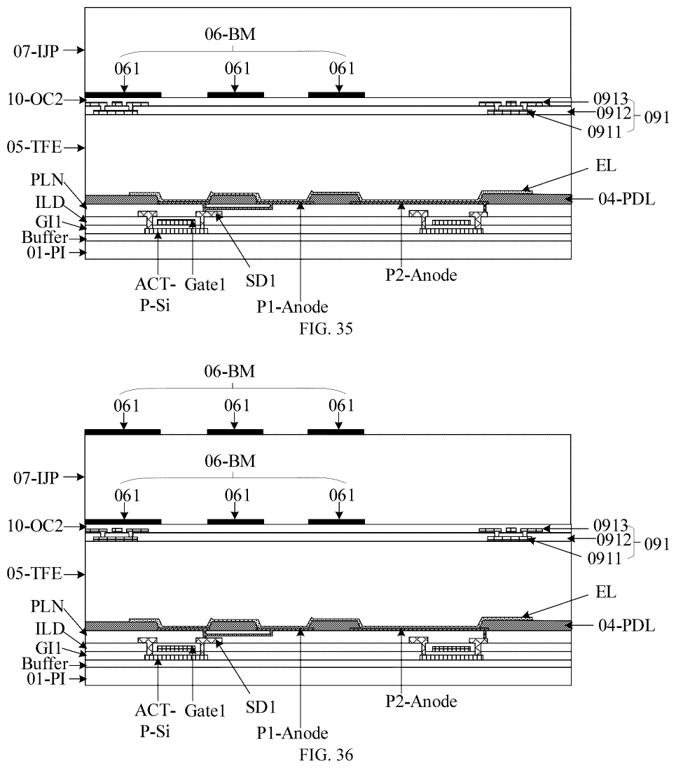

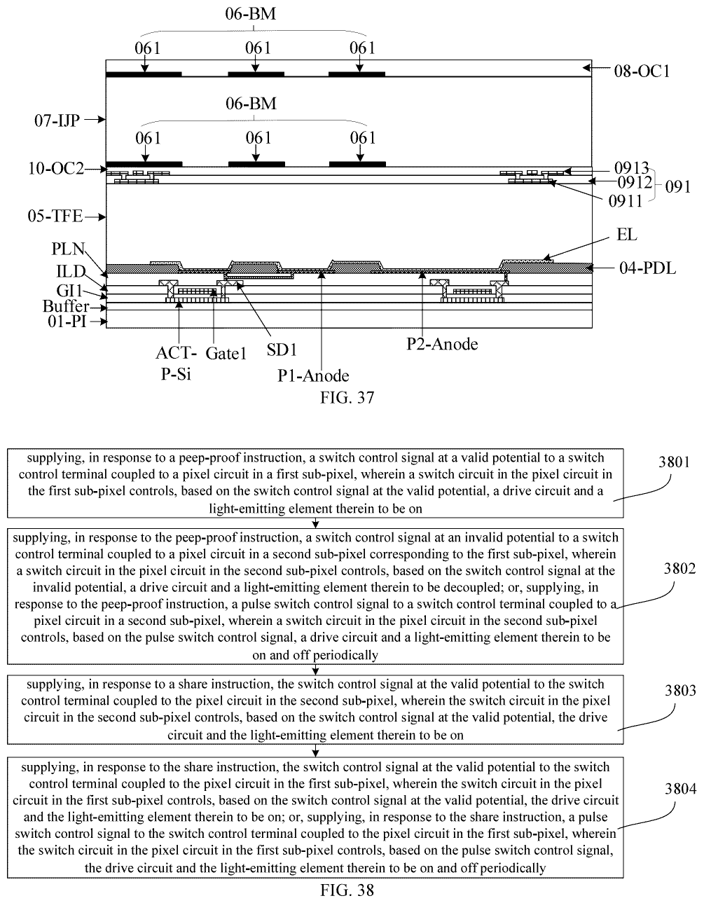

It can be seen by comparing FIG. 26 and FIG. 31 that the formed pixel circuit layer 02 includes two gate metal layers and two gate insulator layers in some embodiments, and the formed pixel circuit layer 02 includes a gate metal layer and a gate insulator layer in some embodiments, which is not limited in the embodiments of the present disclosure. In addition, it should be noted that in the display panels shown in FIG. 26 and FIG. 31 that the formed pixel circuit layer 02 is of a bottom-gate structure. In some embodiments, the formed pixel circuit layer 02 is of a top-gate structure. That is, the gate metal layer is disposed on a side, away from the base substrate 01, of the source and drain metal layer SD.
g. In conjunction with FIG. 32, upon the process f, the encapsulating process is performed. An encapsulation layer 05, or a thin film encapsulation (TFE), is formed on a side, away from the base substrate 01, of the pixel definition layer 04.
h. In conjunction with FIG. 33, upon the process g, an FMLOC is formed on a side, away from the base substrate 01, of the encapsulation layer 05. That is, a plurality of touch electrodes 091 are formed, and each of the plurality of touch electrodes 091 includes a first electrode layer 0911, an interlayer dielectric layer 0912, and a second electrode layer 0913 that are stacked in the direction away from the base substrate 01 in sequence, and an orthographic projection of each of the plurality of touch electrodes 091 on the base substrate 01 is overlapped with an orthographic projection of a portion, between two adjacent of the plurality of pixel unit regions Q11, of the pixel definition layer 04 on the base substrate 01. That is, as shown in FIG. 33, the touch trace is disposed on the pixel definition layer PDL side around the pixel. In addition, a second coating layer 10, also referred to as an OC2 layer, is formed on a side, away from the base substrate 01, of the FMLOC.
i. In conjunction with FIG. 34, upon the process h, a first light-shielding layer 06 is formed on a side, away from the base substrate 01, of the OC2 layer, and the formed first light-shielding layer 06 includes a plurality of light shield portions 061 that are spaced apart, and the light shield portions 061 are at least overlapped with the pixel definition portions 041 defining the first sub-pixels P1 to limit the light emitting angle to achieve the peep-proof function. That is, the first light-shielding layer 06 is manufactured.
j. In conjunction with FIG. 35, upon the process i, a spacer layer 07, that is, an IJP layer, is formed on a side, away from the first light-shielding layer 06 by the IJP process. That is, the IJP film manufacturing is performed.
k. In conjunction with FIG. 36, upon the process j, a second light-shielding layer 06 is formed on a side, away from the base substrate 01, of the IJP layer, and the formed second light-shielding layer 06 includes a plurality of light shield portions 061 that are spaced apart, and the light shield portions 061 are at least overlapped with the pixel definition portions 041 defining the first sub-pixels P1 to limit the light emitting angle to achieve the peep-proof function. In addition, FIG. 27 illustratively shows the light-emitting layer EL. The plurality of light-shielding layers 06 are disposed to limit the light emitting angle and reliably control the peep-proof angle. In some embodiments, the first light-shielding layer 06 and the second light-shielding layer 06 each is a black BM or a black PDL. In some embodiments, the display panel further includes a color filter portion CF between adjacent light shield portions 061.
l. In conjunction with FIG. 37, upon the process k, a first coating layer 08, also referred to as an OC1 layer, is disposed on a side, away from the base substrate 01, of the second light-shielding layer 06. That is, the OC1 layer is manufactured to be determined as an outermost planarization layer.

It should be noted that the processes in the above manufacturing procedure include a deposition processes, a patterning process, and the like. The patterning processes include adhesive coating, exposing, developing, etching, and the like, which are performed in sequence.

In summary, a method for manufacturing a display panel is provided in the embodiments of the present disclosure. The display panel formed by the method includes a plurality of first sub-pixels and a plurality of second sub-pixels on the base substrate. Each of the plurality of first sub-pixels and the plurality of second sub-pixels includes a pixel circuit layer and a light-emitting unit layer that are stacked in a direction away from the base substrate in sequence. The display panel further includes a pixel definition layer and a plurality of light-shielding layers that are disposed on a side of the light-emitting unit layer. As the light shield portions of the light-shielding layers are overlapped with the pixel definition portions defining the first sub-pixels, the plurality of first sub-pixels and the plurality of second sub-pixels are flexibly lightened up to adjust the light emitting angle to switch between peep-proof and sharing. In addition, as the switch circuits controlling the light-emitting element and the drive circuit to be on and off in the plurality of first sub-pixels and the plurality of second sub-pixels are different, the plurality of first sub-pixels and the plurality of second sub-pixels are separately controlled to emit light, such that the peep-proof angle is flexibly adjusted, and the peep-proof flexibility is improved.

Some embodiments of the present disclosure further provide a method for driving a display panel. The method is applicable to the display panel in the above embodiments. As shown in FIG. 38, the method includes the following processes.

In S3801, in response to a peep-proof instruction, a switch control signal at a valid potential is supplied to a switch control terminal coupled to a pixel circuit in a first sub-pixel, wherein a switch circuit in the pixel circuit in the first sub-pixel controls, based on the switch control signal at the valid potential, a drive circuit and a light-emitting element therein to be on.

In S3802, in response to the peep-proof instruction, a switch control signal at an invalid potential is supplied to a switch control terminal coupled to a pixel circuit in a second sub-pixel corresponding to the first sub-pixel, wherein a switch circuit in the pixel circuit in the second sub-pixel controls, based on the switch control signal at the invalid potential, a drive circuit and a light-emitting element therein to be decoupled; or, in response to the peep-proof instruction, a pulse switch control signal is supplied to a switch control terminal coupled to a pixel circuit in a second sub-pixel, wherein a switch circuit in the pixel circuit in the second sub-pixel controls, based on the pulse switch control signal, a drive circuit and a light-emitting element therein to be on and off periodically.

In S3803, in response to a share instruction, the switch control signal at the valid potential is supplied to the switch control terminal coupled to the pixel circuit in the second sub-pixel, wherein the switch circuit in the pixel circuit in the second sub-pixel controls, based on the switch control signal at the valid potential, the drive circuit and the light-emitting element therein to be on.

In S3804, in response to the share instruction, the switch control signal at the valid potential is supplied to the switch control terminal coupled to the pixel circuit in the first sub-pixel, wherein the switch circuit in the pixel circuit in the first sub-pixel controls, based on the switch control signal at the valid potential, the drive circuit and the light-emitting element therein to be on; or, in response to the share instruction, a pulse switch control signal is supplied to the switch control terminal coupled to the pixel circuit in the first sub-pixel, wherein the switch circuit in the pixel circuit in the first sub-pixel controls, based on the pulse switch control signal, the drive circuit and the light-emitting element therein to be on and off periodically.

In the case that the drive circuit and the light-emitting element are conducted, a drive signal generated by the drive circuit is transmitted to the light-emitting element to drive the light-emitting element to emit light.

In some embodiments, the driving principle is illustrated using an example of the pixel circuit shown in FIG. 19, that is, an example where the transistors in the pixel circuit are P-type transistors, the valid potential is a low potential, and the invalid potential is a high potential.

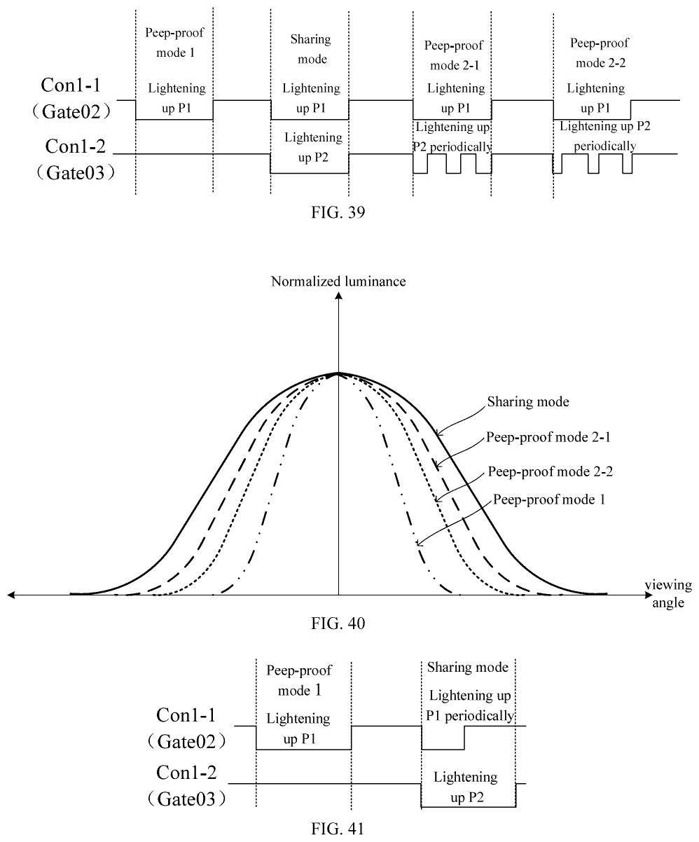

The peep-proof instruction is used to instruct to enter a peep-proof mode, and the share instruction is used to instruct to enter a sharing mode. In conjunction with the signal timing shown in FIG. 39, it can be seen that in the sharing mode, a switch control signal at a low potential is supplied to the switch control terminal Con1-1 (that is, Gate02) coupled to the first sub-pixel P1 (that is, the peep-proof sub-pixel) and the switch control terminal Con1-2 (that is, Gate03) coupled to the second sub-pixel P2 (that is, the normal sub-pixel), such that the first switch transistor T1-1 in the first sub-pixel P1 and the first switch transistor T1-1 in the second sub-pixel P2 are turned on. Furthermore, the drive circuit 0211 shared by the first sub-pixel P1 and the second sub-pixel P2 is conducted to the light-emitting elements 031 in the first sub-pixel P1 and the second sub-pixel P2. Correspondingly, the drive signal generated by the drive circuit 0211 is transmitted to the light-emitting elements 031 in the first sub-pixel P1 and the second sub-pixel P2, such that the first sub-pixel P1 and the second sub-pixel P2 emit light. That is, in the sharing mode, the first sub-pixel P1 and the second sub-pixel P2 are lightened up.

In the peep-proof mode 1, a switch control signal at a low potential is supplied to the switch control terminal Con1-1 (that is, Gate02) coupled to the first sub-pixel P1 (that is, the peep-proof sub-pixel), and a switch control signal at a high potential is supplied to the switch control terminal Con1-2 (that is, Gate03) coupled to the second sub-pixel P2 (that is, the normal sub-pixel), such that the first switch transistor T1-1 in the first sub-pixel P1 is turned on, and the first switch transistor T1-1 in the second sub-pixel P2 is turned off. Furthermore, the drive circuit 0211 shared by the first sub-pixel P1 and the second sub-pixel P2 is conducted to the light-emitting element 031 in the first sub-pixel P1 and are disconnected from the light-emitting element 031 in the second sub-pixel P2. Correspondingly, the drive signal generated by the drive circuit 0211 is transmitted to the light-emitting element 031 in the first sub-pixel P1 to cause the first sub-pixel P1 to emit light, and is not transmitted to the light-emitting element 031 in the second sub-pixel P2. That is, in the peep-proof mode, only the first sub-pixel P1 is lightened up, and the light-shielding layer 06 shielding the light is disposed on a side of the first sub-pixel P1 to achieve the light-shielding effect and the peep-proof.

It can be further seen referring to FIG. 39 that in a peep-proof mode 2-1 and a peep-proof mode 2-2, a switch control signal at a low potential is supplied to the switch control terminal Con1-1 (that is, Gate02) coupled to the first sub-pixel P1 (that is, the peep-proof sub-pixel), and a pulse switch control signal (that is, a pulse signal including a high potential and a low potential) is supplied to the switch control terminal Con1-2 (that is, Gate03) coupled to the second sub-pixel P2 (that is, the normal sub-pixel), such that the first switch transistor T1-1 in the first sub-pixel P1 is turned on, and the first switch transistor T1-1 in the second sub-pixel P2 is on and off periodically (that is, intermittently). That is, the first switch transistor T1-1 in the second sub-pixel P2 is turned on at the high potential and turned off at the low potential. Furthermore, the drive circuit 0211 shared by the first sub-pixel P1 and the second sub-pixel P2 is conducted to the light-emitting elements 031 in the first sub-pixel P1 and are periodically conducted to and disconnected from the light-emitting elements 031 in the second sub-pixel P2. Correspondingly, the drive signal generated by the drive circuit 0211 is transmitted to the light-emitting element 031 in the first sub-pixel P1 to cause the first sub-pixel P1 to emit light, and is periodically transmitted to the light-emitting element 031 in the second sub-pixel P2. That is, in the peep-proof mode, the first sub-pixel P1 is lightened up, and the second sub-pixel P2 is periodically lightened up. That is, the second sub-pixel P2 is lightened up in a pulse driving form. On this basis, light is adjusted by adjusting a duty cycle of the pulse switch control signal. That is, the peep-proof angle is controlled, and the peep-proof flexibility is improved. The logger the duty cycle, the longer the light-emitting duration of the second sub-pixel P2, and the greater the viewing angle. The peep-proof mode 2-1 and the peep-proof mode 2-2 differ in the duty cycle of the switch control signal. The duty cycle may mean a duration of the low potential (that is, the valid potential) in the low potential and the high potential.

In some embodiments, for the sharing mode and three peep-proof modes shown in FIG. 39, FIG. 40 illustrates a viewing angle curve. The horizontal coordinate refers to the viewing angle, and the vertical coordinate refers to the normalized luminance. It can be seen from FIG. 40 that in the peep-proof mode 1, as the second sub-pixel P2 is not lightened up, the peep-proof angle is controlled to a minimum value to achieve a great a peep-proof effect. In the peep-proof modes 2-1 and 2-2, as the second sub-pixel P2 is periodically lightened up, the peep-proof angle is large, and a peep-proof angle in the peep-proof mode 2-1 with a longer duty cycle is larger than a peep-proof angle in the peep-proof mode 2-2 with a shorter duty cycle.

It can be seen based on the above embodiments that in the sharing mode and the peep-proof modes, the first sub-pixel P1 is lightened up for a longer duration than the second sub-pixel P2. That is, a use duration of the first sub-pixel P1 and a use duration of the second sub-pixel P2 are different, such that service lives of the two sub-pixels are inconsistent. Thus, it can be seen referring to the signal timing diagram shown in FIG. 41 that in the embodiments of the present disclosure, the first sub-pixel P1 is lightened up in the pulse driving form in the sharing mode. That is, the pulse switch control signal is supplied to the switch control terminal Con1-1 coupled to the first sub-pixel P1, such that the first sub-pixel P1 is periodically lightened up. As such, the use duration of the first sub-pixel P1 and the use duration of the second sub-pixel P2 are balanced, such that the service life of the first sub-pixel P1 and the service life of the second sub-pixel P2 are consistent as possible, that is, are matched with each other to ensure a great yield of the product.

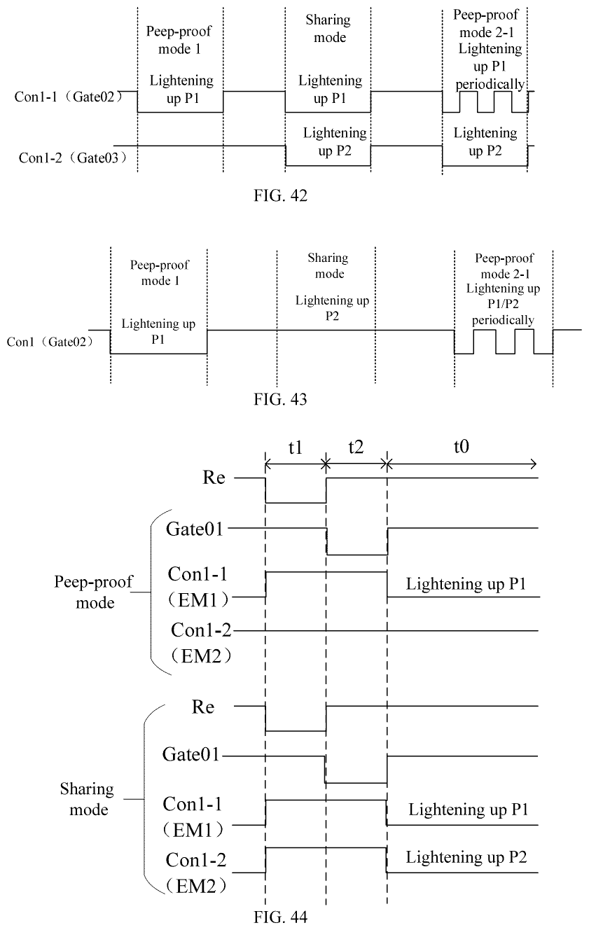

In some embodiments, it can be seen referring to FIG. 15 that an area of the first sub-pixel P1 is greater than an area of the second sub-pixel P2, such that a light-emitting area of the first sub-pixel P1 is greater than a light-emitting area of the second sub-pixel P2. On this basis, referring to the signal timing diagram shown in FIG. 42, the second sub-pixel P2 is lightened up in the pulse driving form. That is, the pulse switch control signal is supplied to the switch control terminal Con1-2 coupled to the second sub-pixel P2, such that the second sub-pixel P2 is periodically lightened up.

In some embodiments, using an example of the pixel circuit shown in FIG. 20, that is, an example where the transistors in the pixel circuit are a P-type transistor and a N-type transistor, it can be seen referring to the signal timing diagram shown in FIG. 43 that a switch control signal at a high potential is supplied to the same switch control terminal Con1 (that is, Gate02) coupled to the first sub-pixel P1 and the second sub-pixel P2, such that the P-type first switch transistor T1-1 in the P-type first sub-pixel P1 is turned off, and the N-type first switch transistor T1-1 in the N-type second sub-pixel P2 is turned on. Furthermore, the drive circuit 0211 shared by the first sub-pixel P1 and the second sub-pixel P2 is conducted to the light-emitting element 031 in the second sub-pixel P2, and is disconnected to the light-emitting element 031 in the first sub-pixel P1. Correspondingly, the drive signal generated by the drive circuit 0211 is transmitted to the light-emitting element 031 in the second sub-pixel P2 to cause the second sub-pixel P2 to emit light, and is not transmitted to the light-emitting element 031 in the first sub-pixel P1. That is, in the sharing mode, only the second sub-pixel P2 is lightened up. As in the embodiments, in the sharing mode, only the second sub-pixel P2 is lightened up and the first sub-pixel P1 is not lightened up, and thus the sharing effect in the sharing mode is endured by controlling the supplied switch control signal to be in the high potential for a longer duration, that is, by lightening up the second sub-pixel P2 for a longer duration.

In the peep-proof mode 1, the switch control signal at the low potential is supplied to the same switch control terminal Con1, such that the P-type first switch transistor T1-1 in the first sub-pixel P1 is turned on, and the N-type first switch transistor T1-1 in the second sub-pixel P2 is turned off. Furthermore, the drive circuit 0211 shared by the first sub-pixel P1 and the second sub-pixel P2 is conducted to the light-emitting element 031 in the first sub-pixel P1 and are disconnected from the light-emitting element 031 in the second sub-pixel P2. Correspondingly, the drive signal generated by the drive circuit 0211 is transmitted to the light-emitting element 031 in the first sub-pixel P1 to cause the first sub-pixel P1 to emit light, and is not transmitted to the light-emitting element 031 in the second sub-pixel P2. That is, in the peep-proof mode 1, only the first sub-pixel P1 is lightened up. In the peep-proof mode 2, the pulse switch control signal is supplied to the same switch control terminal Con1, such that the P-type first switch transistor T1-1 in the first sub-pixel P1 and the N-type first switch transistor T1-1 in the second sub-pixel P2 are on and off periodically. Specifically, the N-type first switch transistor T1-1 in the second sub-pixel P2 is turned on in the case that the potential of the pulse switch control signal is the high potential, and the P-type first switch transistor T1-1 in the first sub-pixel P1 is turned on in the case that the potential of the pulse switch control signal is the low potential. Furthermore, the drive circuit 0211 shared by the first sub-pixel P1 and the second sub-pixel P2 is periodically conducted to and disconnected from the light-emitting element 031 in the first sub-pixel P1 and the light-emitting elements 031 in the second sub-pixel P2. Correspondingly, in the case that the drive circuit 0211 is conducted to the light-emitting element 031 in the first sub-pixel P1, the drive signal generated by the drive circuit 0211 is transmitted to the light-emitting element 031 in the first sub-pixel P1 to cause the first sub-pixel P1 to emit light; and in the case that the drive circuit 0211 is conducted to the light-emitting element 031 in the second sub-pixel P2, the drive signal generated by the drive circuit 0211 is transmitted to the light-emitting element 031 in the second sub-pixel P2 to cause the second sub-pixel P2 to emit light. That is, the first sub-pixel P1 and the second sub-pixel P2 are periodically lightened up in the peep-proof mode 2-1.

In some embodiments, the driving principle is illustrated using an example of the pixel circuit shown in FIG. 22, that is, an example where the transistors in the pixel circuit are P-type transistors, the valid potential is a low potential, and the invalid potential is a high potential.

In conjunction with the signal timing shown in FIG. 44, it can be seen that in the sharing mode, the switch control signal at the low potential is supplied to the switch control terminal Con1-1 (that is, EM1) coupled to the first sub-pixel P1 and the switch control terminal Con1-2 (that is, EM2) coupled to the second sub-pixel P2, such that the first switch transistor T1-1 and the second switch transistor T1-2 in the first sub-pixel P1 and the first switch transistor T1-1 in the second sub-pixel P2 are turned on. Furthermore, a path is formed between the drive power terminal Vdd and the pull-down power terminal Vss coupled to the light-emitting elements 031 in the first sub-pixel P1 and the second sub-pixel P2, and the drive signal generated by the drive circuit 0211 shared by the first sub-pixel P1 and the second sub-pixel P2 is transmitted to the light-emitting elements 031 in the first sub-pixel P1 and the second sub-pixel P2, such that the first sub-pixel P1 and the second sub-pixel P2 emit light. That is, in the sharing mode, the first sub-pixel P1 and the second sub-pixel P2 are lightened up simultaneously.

In the peep-proof mode, the switch control signal at the low potential is supplied to the switch control terminal Con1-1 (that is, EM1) coupled to the first sub-pixel P1, and the switch control signal at the high potential is supplied to the switch control terminal Con1-2 (that is, EM2) coupled to the second sub-pixel P2, such that the first switch transistor T1-1 and the second switch transistor T1-2 in the first sub-pixel P1 are turned on, and the first switch transistor T1-1 in the second sub-pixel P2 is turned off. Furthermore, a path is formed between the drive power terminal Vdd and the pull-down power terminal Vss coupled to the light-emitting element 031 in the first sub-pixel P1, and the drive signal generated by the drive circuit 0211 shared by the first sub-pixel P1 and the second sub-pixel P2 is transmitted to the light-emitting element 031 in the first sub-pixel P1 to cause the first sub-pixel P1 to emit light, and is not transmitted to the light-emitting element 031 in the second sub-pixel P2. That is, in the peep-proof mode, only the first sub-pixel P1 is lightened up. The phase of lightening up the first sub-pixel P1 and/or the second sub-pixel P2 is referred to as a light-emitting phase to.

In addition, FIG. 44 further shows the reset signal supplied by the reset signal terminal Re and the gate drive signal supplied by the gate signal terminal Gate01. In the reset phase t2, a potential of the supplied reset signal is the low potential, such that the first reset transistor T5 and the sixth reset transistor T6 are turned on. Furthermore, a first initial power signal supplied by the first initial power terminal Vinit1 is transmitted to the gate electrode of the second drive transistor T3-2 to reset the gate electrode of the second drive transistor T3-2, and a second initial power signal supplied by the second initial power terminal Vinit2 is transmitted to the anode of the light-emitting element 031 to reset the anode of the light-emitting element 031. In the data write phase t1, a potential of the supplied gate drive signal is the low potential, such that the second data write transistor T2-2 and the compensation transistor T4 are turned on, and the data signal supplied by the data signal terminal Vdata is transmitted to the gate electrode of the second drive transistor T3-2. In the light-emitting phase t0 in the above embodiments, the second drive transistor T3-2 reliably generates, based on the potential of the gate and the drive power signal supplied by the drive power terminal Vdd, the drive signal for driving the light-emitting element 031 to emit light.

In some embodiments, the driving principle is illustrated using an example of the pixel circuit shown in FIG. 23, that is, an example where the transistors in the pixel circuit are P-type transistors and N-type transistors.

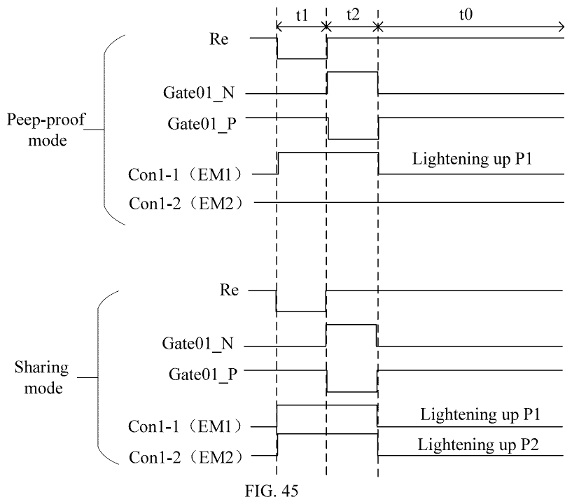

In conjunction with the signal timing shown in FIG. 45, it can be seen that in the light-emitting phase t0, the switch control signal supplied to the switch control terminal Con1-1 (including EM1 and EM2) is the same as the signal shown in FIG. 44. Thus, similarly, the first sub-pixel P1 and the second sub-pixel P2 are lightened up simultaneously in the sharing mode, and only the first sub-pixel P1 is lightened up in the peep-proof mode. In the reset phase t2, the reset signal supplied to the reset signal terminal Re is the same as the signal shown in FIG. 44. Thus, similarly, the gate electrode of the second drive transistor T3-2 and the anode of the light-emitting element 031 are reset, and the seventh reset transistor T7 therein is turned on, such that the third initial power signal supplied by the third initial power terminal Vinit3 is transmitted to the first electrode of the second drive transistor T3-2 to reset the first electrode of the second drive transistor T3-2. FIG. 45 and FIG. 44 differ in that the transistors in the pixel circuit are P-type transistors and N-type transistors, and thus in the data write phase t1, in FIG. 45, the gate drive signal at the low potential is supplied to the gate signal terminal Gate01_P coupled to the P-type second data write transistor T2-2 and the compensation transistor T4, and the gate drive signal at the high potential is supplied to the gate signal terminal Gate01_N coupled to the N-type switch control transistor T8, such that the second data write transistor T2-2, the compensation transistor T4, and the switch control transistor T8 are turned on, and the data signal supplied by the data signal terminal Vdata is reliably transmitted to the gate electrode of the second drive transistor T3-2. In the light-emitting phase t0, the second drive transistor T3-2 reliably generates, based on the potential of the gate and the drive power signal supplied by the drive power terminal Vdd, the drive signal for driving the light-emitting element 031 to emit light.

In some embodiments, the driving principle is illustrated using an example of the pixel circuit shown in FIG. 24.

In conjunction with the signal timing shown in FIG. 45, it can be seen that in the light-emitting phase t0, the switch control signal supplied to the switch control terminal Con1-1 (including EM1 and EM2) is the same as the signal shown in FIG. 44. Thus, in the sharing mode, the first switch transistor T1-1 and the second switch transistor T1-2 in the first sub-pixel P1 are turned on, and the first switch transistor T1-1 and the second switch transistor T1-2 in the second sub-pixel P2 are also turned on. Furthermore, a path is formed between the drive power terminal Vdd and the pull-down power terminal Vss coupled to the light-emitting elements 031 in the first sub-pixel P1 and the second sub-pixel P2, and the drive signal generated by the drive circuit 0211 shared by the first sub-pixel P1 and the second sub-pixel P2 is transmitted to the light-emitting elements 031 in the first sub-pixel P1 and the second sub-pixel P2, such that the first sub-pixel P1 and the second sub-pixel P2 emit light. That is, in the sharing mode, the first sub-pixel P1 and the second sub-pixel P2 are lightened up simultaneously. Alternatively, in the sharing mode in some embodiments, the switch control signal at the low potential is only supplied to the switch control terminal Con1-2 (that is, EM2) coupled to the second sub-pixel P2, and the switch control signal at the high potential is supplied to the switch control terminal Con1-1 (that is, EM1) coupled to the first sub-pixel P1, such that the first switch transistor T1-1 and the second switch transistor T1-2 in the second sub-pixel P2 are turned on, and the first switch transistor T1-1 and the second switch transistor T1-2 in the first sub-pixel P1 are turned off. Furthermore, a path is formed between the drive power terminal Vdd and the pull-down power terminal Vss coupled to the light-emitting element 031 in the second sub-pixel P2, and the drive signal generated by the drive circuit 0211 shared by the first sub-pixel P1 and the second sub-pixel P2 is transmitted to the light-emitting element 031 in the second sub-pixel P2 to cause the second sub-pixel P2 to emit light, and is not transmitted to the light-emitting element 031 in the first sub-pixel P1. That is, in the sharing mode, only the second sub-pixel P2 is lightened up. In the drawing, the sharing mode simultaneously lightening up the first sub-pixel P1 and the second sub-pixel P2 is marked as the sharing mode 1, and the sharing mode only lightening up the second sub-pixel P2 is marked as the sharing mode 2.

In the peep-proof mode, the first switch transistor T1-1 and the second switch transistor T1-2 in the first sub-pixel P1 are turned on, and the first switch transistor T1-1 and the second switch transistor T1-2 in the second sub-pixel P2 are turned off. Furthermore, a path is formed between the drive power terminal Vdd and the pull-down power terminal Vss coupled to the light-emitting element 031 in the first sub-pixel P1, and the drive signal generated by the drive circuit 0211 shared by the first sub-pixel P1 and the second sub-pixel P2 is transmitted to the light-emitting element 031 in the first sub-pixel P1 to cause the first sub-pixel P1 to emit light, and is not transmitted to the light-emitting element 031 in the second sub-pixel P2. That is, in the peep-proof mode, only the first sub-pixel P1 is lightened up.

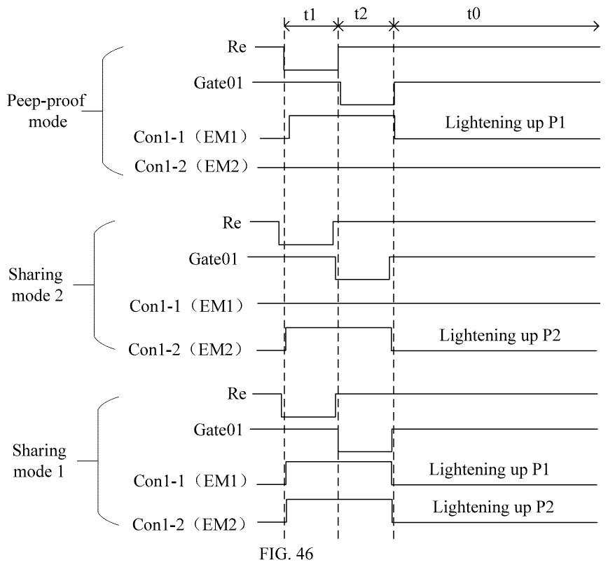

In addition, it can be seen referring to the signal timing diagram shown in FIG. 46 that, in the reset phase t2, the reset signal supplied to the reset signal terminal Re is the same as the signal shown in FIG. 44. Thus, similarly, the gate electrode of the second drive transistor T3-2 and the anode of the light-emitting element 031 are reset. In the data write phase t1, the gate drive signal supplied to the gate signal terminal Gate01 is the same as the signal shown in FIG. 44. Thus, similarly, the data signal is written, such that the second drive transistor T3-2 reliably generates the drive signal.

It should be noted that for the pixel circuits shown in FIG. 22 to FIG. 24, the sub-pixel may be driven to emit light in a pulse form to flexibly control the peep-proof angle. The above signal timing are illustrative. In addition, each signal terminal coupled to the pixel circuit may be coupled to the driver chip to receive the above signal supplied by the driver chip.

In summary, a method for driving a display panel is provided in the embodiments of the present disclosure. In the method, in the peep-proof mode and the sharing mode, the plurality of first sub-pixels and the plurality of second sub-pixels that are in one-to-one correspondence are flexibly lightened up, and the switch circuits controlling the light-emitting element and the drive circuit to be on and off in the plurality of first sub-pixels and the plurality of second sub-pixels are different. Thus, the light emitting angle is adjusted by flexibly lightening up the plurality of first sub-pixels and the plurality of second sub-pixels to switch between peep-proof and sharing. In addition, the plurality of first sub-pixels and the plurality of second sub-pixels are separately controlled to emit light, such that the peep-proof angle is flexibly adjusted, and the peep-proof flexibility is improved.

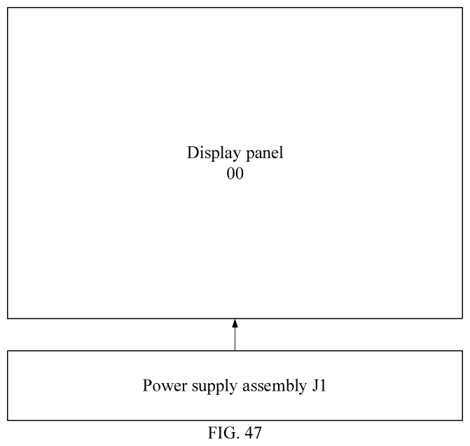

FIG. 47 is a schematic structural diagram of a display device according to some embodiments of the present disclosure. As shown in FIG. 47, the display device includes a power supply assembly J1, and the display panel 00 in the above embodiments.

The power supply assembly J1 is coupled to the display panel 00 and is configured to supply power to the display panel 00.

In some embodiments, the display device according to the embodiments of the present disclosure is an organic light-emitting diode (OLED) display device, an active-matrix OLED (AMOLED) display device, or any other products or components with the display function.

The terms used in the embodiments of the present disclosure are only used to explain the embodiments of the present disclosure, and are not intended to limit the present disclosure. Unless otherwise defined, technical or scientific terms used in the present disclosure shall have ordinary meaning understood by persons of ordinary skill in the art to which the disclosure belongs.

For example, the terms “first,” “second,” and “third” are not intended to indicate or imply any sequence, number or importance, and are only used to distinguish different portions.

Similarly, the terms “a,” “an,” and the like are not intended to limit the quantity, and only represent that at least one exists.

The terms “include” or “include” and the like are used to indicate that the element or object preceding the terms covers the element or object following the terms and its equivalents, and shall not be understood as excluding other elements or objects.

The terms “on,” “under,” “left,” and “right” are only used to indicate the relative positional relationship. When the absolute position of the described object changes, the relative positional relationship may change accordingly. The terms “connection” and “coupling” refer to electrical connection.

The term “and/or” herein describes associations between associated objects, and indicates three types of relationships. For example, the phrase “A and/or B” means (A), (B), or (A and B). The symbol “/” generally indicates an “or” relationship between the associated objects.

Those skilled in the art should clearly understand that for the convenience and simplicity of description, for the specific operating process of the circuits and subcircuits described above, reference may be made to the corresponding processes in the method embodiments, which is not repeated herein.

Described above are merely optional embodiments of the present disclosure, and are not intended to limit the present disclosure. Any modifications, equivalent replacements, improvements and the like made within the spirit and principles of the present disclosure should be encompassed within the scope of protection of the present disclosure.

1. A display panel, comprising:
a base substrate, comprising a plurality of pixel sub-regions, wherein each of the plurality of pixel sub-regions comprises a plurality of pixel unit regions, each of the plurality of pixel unit regions comprising a first pixel unit region and a second pixel unit region;
a plurality of first sub-pixels and a plurality of second sub-pixels that are in one-to-one correspondence and have different colors in the plurality of pixel unit regions in the plurality of pixel sub-regions, wherein the plurality of first sub-pixels are disposed in the first pixel unit region, the plurality of second sub-pixels are disposed in the second pixel unit region, and each of the plurality of first sub-pixels and the plurality of second sub-pixels comprises a pixel circuit layer and a light-emitting unit layer that are stacked in a direction away from the base substrate in sequence; and
a pixel definition layer, an encapsulation layer, and a plurality of light-shielding layers that are stacked on a side of the light-emitting unit layer in the direction away from the base substrate in sequence, wherein the pixel definition layer comprises a plurality of openings and a plurality of pixel definition portions surrounding the plurality of openings, light-emitting unit layers of any adjacent two sub-pixels in the plurality of first sub-pixels and the plurality of second sub-pixels are disposed in one of the plurality of openings and defined by the pixel definition layer, the plurality of light-shielding layers comprise a plurality of light shield portions that are spaced apart, and an orthographic projection of each of the plurality of light shield portions on the base substrate is overlapped with an orthographic projection of one of the plurality of pixel definition portions defining the plurality of first sub-pixels on the base substrate;
wherein the pixel circuit layer is configured to form a pixel circuit, and the light-emitting unit layer is configured to form a light-emitting element, wherein the pixel circuit comprises a drive circuit and a switch circuit, and pixel circuits in the plurality of first sub-pixels and the plurality of second sub-pixels that are in one-to-one correspondence comprise different switch circuits and share a same drive circuit;
wherein the switch circuit is coupled to a switch control terminal, the drive circuit, and the light-emitting element, and is configured to control, based on a switch control signal supplied by the switch control terminal, the drive circuit and the light-emitting element to be on and off, and the drive circuit is configured to generate a drive signal for driving the light-emitting element to emit light.

2. The display panel according to claim 1, wherein in the plurality of first sub-pixels and the plurality of second sub-pixels that are in one-to-one correspondence, an area of the light-emitting element in each of the plurality of first sub-pixels is less than an area of the light-emitting element in each of the plurality of second sub-pixels.

3. The display panel according to claim 1, wherein the first pixel unit region comprises a plurality of pixel unit sub-regions defined by the plurality of pixel definition portions, and the light-emitting unit layer comprises an anode, a light-emitting layer, and a cathode that are stacked in the direction away from the base substrate in sequence, wherein the anode of each of the plurality of first sub-pixels in the first pixel unit region comprises a plurality of anode portions coupled to each other in the plurality of pixel unit sub-regions.

4. The display panel according to claim 3, wherein shapes of the plurality of pixel unit sub-region in the first pixel unit region are different from a shape of the second pixel unit region.

5. The display panel according to claim 1, further comprising:
a spacer layer between each two adjacent layers of the plurality of light-shielding layers;
a first overcoat layer on a side, away from the base substrate, of the plurality of light-shielding layers;
a touch layer and a second overcoat layer between the encapsulation layer and the plurality of light-shielding layers and stacked in the direction away from the base substrate in sequence; wherein the touch layer comprises a plurality of touch electrodes that are spaced apart, wherein each of the plurality of touch electrodes comprises an interlayer dielectric layer, a first electrode layer, and a second electrode layer that are stacked in the direction away from the base substrate in sequence, and an orthographic projection of each of the plurality of touch electrodes on the base substrate is overlapped with an orthographic projection of a portion, between two adjacent of the plurality of pixel unit regions, of the pixel definition layer on the base substrate.

6. The display panel according to claim 1, wherein the display panel comprises two light-shielding layers, wherein a distance between the two light-shielding layers is greater than 5 microns, and each of the two light-shielding layers comprises a black matrix layer or a black pixel definition layer.

7. The display panel according to claim 1, further comprising: a color filter portion between each two adjacent of the plurality of light shield portions in at least one layer of the plurality of light-shielding layers.

8. The display panel according to claim 1, wherein in the plurality of first sub-pixels and the plurality of second sub-pixels that are in one-to-one correspondence, the drive circuit of each of the sub-pixels is coupled to a gate signal terminal, a data signal terminal, and a drive power terminal and is configured to generate the drive signal based on a gate drive signal supplied by the gate signal terminal, a data signal supplied by the data signal terminal, and a drive power signal supplied by the drive power terminal, and the switch circuit of each of the sub-pixels comprises a first switch transistor, wherein a gate electrode of the first switch transistor is coupled to the switch control terminal, a first electrode of the first switch transistor is coupled to the drive circuit, and a second electrode of the first switch transistor is coupled to the light-emitting element.

9. The display panel according to claim 8, wherein the drive circuit of each of the sub-pixels further comprises a first data write transistor, a first drive transistor, and a first storage capacitor, wherein a gate electrode of the first data write transistor is coupled to the gate signal terminal, a first electrode of the first data write transistor is coupled to the data signal terminal, and a second electrode of the first data write transistor is coupled to a first terminal of the first storage capacitor; a second terminal of the first storage capacitor is coupled to the drive power terminal; and a gate electrode of the first drive transistor is coupled to the first terminal of the first storage capacitor, a first electrode of the first drive transistor is coupled to the drive power terminal, and a second electrode of the first drive transistor is coupled to the first electrode of the first switch transistor.

10. The display panel according to claim 8, wherein in the plurality of first sub-pixels and the plurality of second sub-pixels that are in one-to-one correspondence, the switch circuit of at least one sub-pixel is coupled to the drive power terminal and the drive circuit, is configured to control, based on the switch control signal, the drive power terminal and the drive circuit to be on and off, and further comprises a second switch transistor, wherein a gate electrode of the second switch transistor is coupled to the switch control terminal, a first electrode of the second switch transistor is coupled to the drive power terminal, and a second electrode of the second switch transistor is coupled to the drive circuit.

11. The display panel according to claim 10, wherein the drive circuit of each of the sub-pixels comprises a second data write transistor, a second drive transistor, a compensation transistor, and a second storage capacitor, wherein a gate electrode of the second data write transistor and a gate electrode of the compensation transistor are coupled to the gate signal terminal, a first electrode of the second data write transistor is coupled to the data signal terminal, and a second electrode of the second data write transistor is coupled to a first electrode of the second drive transistor; a first electrode of the compensation transistor is coupled to a second electrode of the second drive transistor, and a second electrode of the compensation transistor is coupled to a gate electrode of the second drive transistor; a first electrode of the second drive transistor is coupled to the second electrode of the second switch transistor; and a first terminal of the second storage capacitor is coupled to the gate electrode of the second drive transistor, and a second terminal of the second storage capacitor is coupled to the drive power terminal.

12. The display panel according to claim 9, wherein
in different switch circuits in the pixel circuits in the plurality of first sub-pixels and the plurality of second sub-pixels that are in one-to-one correspondence, types of switch transistors are the same, and the different switch circuits are coupled to different switch control terminals; or
in different switch circuits in the pixel circuits in the plurality of first sub-pixels and the plurality of second sub-pixels that are in one-to-one correspondence, types of switch transistors are different, and the different switch circuits share a same switch control terminal.

13. The display panel according to claim 1, wherein
the display panel comprises a plurality of first pixels in the plurality of pixel sub-regions, wherein each of the plurality of first pixels comprises a plurality of sub-pixels in different colors, each of the plurality of sub-pixels comprising one of the plurality of first sub-pixels and one of the plurality of second sub-pixels that are in one-to-one correspondence; or
the display panel comprises a plurality of first pixels and a plurality of second pixels in the plurality of pixel sub-regions, wherein each of the plurality of first pixels comprises the plurality of first sub-pixels in different colors, and each of the plurality of second pixels comprises the plurality of second sub-pixels that are in one-to-one correspondence to the plurality of first sub-pixels in different colors.

14. A method for manufacturing a display panel, applicable to manufacturing the display panel as defined in claim 1, the method comprising:
providing a base substrate, the base substrate comprising a plurality of pixel sub-regions, wherein each of the plurality of pixel sub-regions comprises a plurality of pixel unit regions, each of the plurality of pixel unit regions comprising a first pixel unit region and a second pixel unit region;
forming a plurality of first sub-pixels and a plurality of second sub-pixels that are in one-to-one correspondence and have different colors in the plurality of pixel unit regions in the plurality of pixel sub-regions, wherein the plurality of first sub-pixels are disposed in the first pixel unit region, the plurality of second sub-pixels are disposed in the second pixel unit region, and each of the plurality of first sub-pixels and the plurality of second sub-pixels comprises a pixel circuit layer and a light-emitting unit layer that are stacked in a direction away from the base substrate in sequence, wherein the pixel circuit layer is configured to form a pixel circuit, and the light-emitting unit layer is configured to form a light-emitting element; and
forming a pixel definition layer, an encapsulation layer, and a plurality of light-shielding layers that are stacked on a side of the light-emitting unit layer in the direction away from the base substrate in sequence, wherein the formed pixel definition layer comprises a plurality of openings and a plurality of pixel definition portions surrounding the plurality of openings, light-emitting unit layers of any adjacent two sub-pixels in the plurality of first sub-pixels and the plurality of second sub-pixels are disposed in one of the plurality of openings and defined by one of the plurality of pixel definition portions, the plurality of formed light-shielding layers comprise a plurality of light shield portions that are spaced apart, and an orthographic projection of each of the plurality of light shield portions on the base substrate is overlapped with an orthographic projection of one of the plurality of pixel definition portions defining the plurality of first sub-pixels on the base substrate;
wherein the formed pixel circuit comprises a drive circuit and a switch circuit, and pixel circuits in the plurality of first sub-pixels and the plurality of second sub-pixels that are in one-to-one correspondence comprise different switch circuits and share a same drive circuit;
wherein the switch circuit is coupled to a switch control terminal, the drive circuit, and the light-emitting element, and is configured to control, based on a switch control signal supplied by the switch control terminal, the drive circuit and the light-emitting element to be on and off, and the drive circuit is configured to generate a drive signal for driving the light-emitting element to emit light.

15. A method for driving a display panel, applicable to the display panel as defined in claim 1, the method comprising:
supplying, in response to a peep-proof instruction, a switch control signal at a valid potential to a switch control terminal coupled to a pixel circuit in a first sub-pixel, wherein a switch circuit in the pixel circuit in the first sub-pixel controls, based on the switch control signal at the valid potential, a drive circuit and a light-emitting element therein to be on;
supplying, in response to the peep-proof instruction, a switch control signal at an invalid potential to a switch control terminal coupled to a pixel circuit in a second sub-pixel corresponding to the first sub-pixel, wherein a switch circuit in the pixel circuit in the second sub-pixel controls, based on the switch control signal at the invalid potential, a drive circuit and a light-emitting element therein to be decoupled; or, supplying, in response to the peep-proof instruction, a pulse switch control signal to a switch control terminal coupled to a pixel circuit in a second sub-pixel, wherein a switch circuit in the pixel circuit in the second sub-pixel controls, based on the pulse switch control signal, a drive circuit and a light-emitting element therein to be on and off periodically;
supplying, in response to a share instruction, the switch control signal at the valid potential to the switch control terminal coupled to the pixel circuit in the second sub-pixel, wherein the switch circuit in the pixel circuit in the second sub-pixel controls, based on the switch control signal at the valid potential, the drive circuit and the light-emitting element therein to be on; and
supplying, in response to the share instruction, the switch control signal at the valid potential to the switch control terminal coupled to the pixel circuit in the first sub-pixel, wherein the switch circuit in the pixel circuit in the first sub-pixel controls, based on the switch control signal at the valid potential, the drive circuit and the light-emitting element therein to be on; or, supplying, in response to the share instruction, a pulse switch control signal to the switch control terminal coupled to the pixel circuit in the first sub-pixel, wherein the switch circuit in the pixel circuit in the first sub-pixel controls, based on the pulse switch control signal, the drive circuit and the light-emitting element therein to be on and off periodically;
wherein in the case that the drive circuit and the light-emitting element are conducted, a drive signal generated by the drive circuit is transmitted to the light-emitting element to drive the light-emitting element to emit light.

16. A display device, comprising: a power supply assembly, and a display panel; wherein
the display device comprises: display panel, comprising:
a base substrate, comprising a plurality of pixel sub-regions, wherein each of the plurality of pixel sub-regions comprises a plurality of pixel unit regions, each of the plurality of pixel unit regions comprising a first pixel unit region and a second pixel unit region;
a plurality of first sub-pixels and a plurality of second sub-pixels that are in one-to-one correspondence and have different colors in the plurality of pixel unit regions in the plurality of pixel sub-regions, wherein the plurality of first sub-pixels are disposed in the first pixel unit region, the plurality of second sub-pixels are disposed in the second pixel unit region, and each of the plurality of first sub-pixels and the plurality of second sub-pixels comprises a pixel circuit layer and a light-emitting unit layer that are stacked in a direction away from the base substrate in sequence; and
a pixel definition layer, an encapsulation layer, and a plurality of light-shielding layers that are stacked on a side of the light-emitting unit layer in the direction away from the base substrate in sequence, wherein the pixel definition layer comprises a plurality of openings and a plurality of pixel definition portions surrounding the plurality of openings, light-emitting unit layers of any adjacent two sub-pixels in the plurality of first sub-pixels and the plurality of second sub-pixels are disposed in one of the plurality of openings and defined by the pixel definition layer, the plurality of light-shielding layers comprise a plurality of light shield portions that are spaced apart, and an orthographic projection of each of the plurality of light shield portions on the base substrate is overlapped with an orthographic projection of one of the plurality of pixel definition portions defining the plurality of first sub-pixels on the base substrate;
wherein the pixel circuit layer is configured to form a pixel circuit, and the light-emitting unit layer is configured to form a light-emitting element, wherein the pixel circuit comprises a drive circuit and a switch circuit, and pixel circuits in the plurality of first sub-pixels and the plurality of second sub-pixels that are in one-to-one correspondence comprise different switch circuits and share a same drive circuit; wherein the switch circuit is coupled to a switch control terminal, the drive circuit, and the light-emitting element, and is configured to control, based on a switch control signal supplied by the switch control terminal, the drive circuit and the light-emitting element to be on and off, and the drive circuit is configured to generate a drive signal for driving the light-emitting element to emit light; and
the power supply assembly is coupled to the display panel and is configured to supply power to the display panel.

17. The display device according to claim 16, wherein in the plurality of first sub-pixels and the plurality of second sub-pixels that are in one-to-one correspondence, an area of the light-emitting element in each of the plurality of first sub-pixels is less than an area of the light-emitting element in each of the plurality of second sub-pixels.

18. The display device according to claim 16, wherein the first pixel unit region comprises a plurality of pixel unit sub-regions defined by the plurality of pixel definition portions, and the light-emitting unit layer comprises an anode, a light-emitting layer, and a cathode that are stacked in the direction away from the base substrate in sequence, wherein the anode of each of the plurality of first sub-pixels in the first pixel unit region comprises a plurality of anode portions coupled to each other in the plurality of pixel unit sub-regions.

19. The display device according to claim 16, wherein the display panel further comprises:
a spacer layer between each two adjacent layers of the plurality of light-shielding layers;
a first overcoat layer on a side, away from the base substrate, of the plurality of light-shielding layers;
a touch layer and a second overcoat layer between the encapsulation layer and the plurality of light-shielding layers and stacked in the direction away from the base substrate in sequence; wherein the touch layer comprises a plurality of touch electrodes that are spaced apart, wherein each of the plurality of touch electrodes comprises an interlayer dielectric layer, a first electrode layer, and a second electrode layer that are stacked in the direction away from the base substrate in sequence, and an orthographic projection of each of the plurality of touch electrodes on the base substrate is overlapped with an orthographic projection of a portion, between two adjacent of the plurality of pixel unit regions, of the pixel definition layer on the base substrate.

20. The display device according to claim 16, wherein the display panel further comprises: a color filter portion between each two adjacent of the plurality of light shield portions in at least one layer of the plurality of light-shielding layers.
